(19) United States
(12) Patent Application Publication
(10) Pub. No.: US 2025/0061947 A1
(43) Pub. Date: Feb. 20, 2025

(54) APPARATUS AND METHODS FOR ERASING FOR NON-VOLATILE MEMORY

(71) Applicant: Western Digital Technologies, Inc., San Jose, CA (US)

(72) Inventors: Yi Song, San Jose, CA (US); Ken Oowada, Fujisawa (JP); Jiahui Yuan, Fremont, CA (US)

(73) Assignee: Western Digital Technologies, Inc., San Jose, CA (US)

(21) Appl. No.: 18/452,500

(22) Filed: Aug. 18, 2023

(51) Int. Cl. G11C 16/16; G06F 12/02; G11C 16/34

(52) U.S. Cl. CPC G11C 16/16; G06F 12/0246; G11C 16/3445; G06F 2212/7201

(57) ABSTRACT

An apparatus is provided that includes a block of memory cells, and a control circuit coupled to the block of memory cells. The control circuit is configured to perform an erase operation on the block of memory cells by receiving a desired amount of variation from a baseline erase pulse parameter, generating a first erase pulse that includes the desired amount of variation from the baseline erase pulse parameter, and applying the first erase pulse to the block of memory cells. The desired amount of variation from the baseline erase pulse is selected to reduce erase-induced damage to the block of memory cells.

### BACKGROUND

Semiconductor memory is widely used in various electronic devices such as cellular telephones, digital cameras, personal digital assistants, medical electronics, mobile computing devices, servers, solid state drives, non-mobile computing devices and other devices. Semiconductor memory may comprise non-volatile memory or volatile memory. A non-volatile memory allows information to be stored and retained even when the non-volatile memory is not connected to a source of power (e.g., a battery). Examples of non-volatile memory include flash memory (e.g., NAND-type and NOR-type flash memory).

Memory systems can be used to store data provided by a host device (or other client). However, various challenges are presented in operating such memory systems. In particular, as memory cells decrease in size and memory arrays increase in density, maintaining the integrity of data being stored becomes more challenging.

### BRIEF DESCRIPTION OF THE DRAWINGS

Like-numbered elements refer to common components in the different figures.

FIG. 1 is a block diagram depicting one embodiment of a memory system.

FIG. 2 is a block diagram of one embodiment of a memory die.

FIG. 3 is a perspective view of a portion of one embodiment of a three dimensional memory structure.

FIG. 4A is a block diagram of a memory structure having two planes.

FIG. 4B depicts a top view of a portion of a block of memory cells.

FIG. 4C depicts a cross sectional view of a portion of a block of memory cells.

FIG. 4D depicts a view of the select gate layers and word line layers.

FIG. 4E is a cross sectional view of a memory hole of memory cells.

FIG. 4F is a schematic of a plurality of NAND strings.

FIG. 5 depicts threshold voltage distributions.

FIG. 6 is a table describing one example of an assignment of data values to data states.

FIGS. 7A-7E depict various threshold voltage distributions and describe a process for programming non-volatile memory.

FIG. 8 is a flowchart describing an embodiment of a process for programming non-volatile memory.

FIG. 9 depicts a word line voltage during programming and verify operations.

FIG. 10A depicts a flowchart describing an embodiment of a process for erasing a population of memory cells.

FIG. 10B depicts example erase voltage pulses.

FIG. 11 depicts example erased threshold voltage distributions for a population of memory cells.

FIG. 12A depicts a flowchart describing an embodiment of a process for erasing a population of memory cells.

FIG. 12B depicts an example of erase voltage pulses.

FIG. 12C depicts another example of erase voltage pulses.

FIG. 12D depicts still another example of erase voltage pulses.

FIG. 13 depicts a flowchart describing an embodiment of a process for erasing a memory cell using gate induced drain leakage.

### DETAILED DESCRIPTION

Memory cells often experience “cycling damage” caused by high electric fields across the memory cells during erase operations. Without wanting to be bound by any particular theory, it is believed that reducing electric fields across the memory cells during erase operations may reduce such cycling damage. Technology is described for erasing memory cells by applying a “weaker” first erase pulse, then resuming “normal” erase pulses for the second and any subsequent erase pulses applied to the memory cells.

In an embodiment, an erase voltage of the first erase pulse is lower than a baseline initial erase voltage. In another embodiment, an erase pulse width of the first erase pulse is shorter than a baseline erase pulse width. In another embodiment, an erase voltage of the first erase pulse is lower than a baseline initial erase voltage, and an erase pulse width of the first erase pulse is shorter than a baseline erase pulse width. In embodiments, any second and subsequent erase pulses have erase voltages and erase pulse widths that are based on the baseline initial erase voltage and the baseline erase pulse width, respectively.

Without wanting to be bound by any particular theory, it is believed that erasing memory cells using a first erase pulse that includes an erase voltage that is lower than a baseline initial erase voltage, and/or an erase pulse width that is shorter than a baseline erase pulse width may reduce erase-induced damage to the memory cells.

Some non-volatile memory devices are used to store two ranges of charges and, therefore, the memory cells can be programmed/erased between two data states: an erased state and a programmed state (corresponding to data “1” and data “0”). Such a device is referred to as a binary device or a single-level cell (SLC) and the data are binary data. In contrast, a multi-state flash memory cell (storing multi-state data) is implemented by identifying multiple, distinct allowed threshold voltage ranges.

Each distinct threshold voltage range corresponds to a predetermined value for the set of data bits. For example, some memory cells can store two or more bits. The specific relationship between the data programmed into the memory cell and the threshold voltage ranges of the memory cell depends upon the data encoding scheme adopted for the memory cells.

In addition to the gains in capacity resulting from multi-state memory architectures, significant advantages in memory technology have resulted from steadily scaling down the physical dimensions of memory cells. Smaller memory cells can be packed more densely on a given die area, allowing higher memory capacity for the same price as an older memory technology.

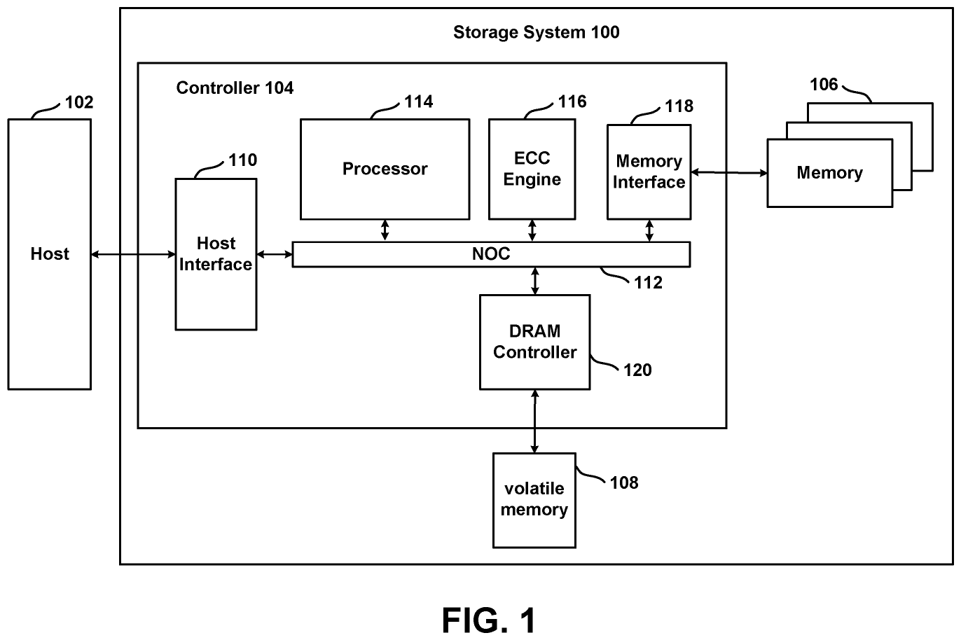

FIG. 1 is a block diagram of an embodiment of a memory system 100 that implements the described technology. In an embodiment, memory system 100 is a solid state drive (“SSD”). Memory system 100 also can be a memory card, USB drive or other type of storage system. The proposed technology is not limited to any one type of memory system. Memory system 100 is connected to host 102, which can be a computer, server, electronic device (e.g., smart phone, tablet or other mobile device), appliance, or another apparatus that uses memory and has data processing capabilities. In some embodiments, host 102 is separate from, but connected to, memory system 100. In other embodiments, memory system 100 is embedded within host 102.

The components of memory system 100 depicted in FIG. 1 are electrical circuits. Memory system 100 includes a controller 104 connected to one or more memory die 106 and local high speed volatile memory 108 (e.g., DRAM). The one or more memory die 106 each include a plurality of non-volatile memory cells. More information about the structure of each memory die 106 is provided below. Local high speed volatile memory 108 is used by controller 104 to perform certain functions. For example, local high speed volatile memory 108 stores logical to physical address translation tables (“L2P tables”)

Controller 104 includes a host interface 110 that is connected to and in communication with host 102. In one embodiment, host interface 110 provides a PCle interface. Other interfaces can also be used, such as SCSI, SATA, etc. Host interface 110 is also connected to a network-on-chip (NOC) 112, which is a communication subsystem on an integrated circuit. In other embodiments, NOC 112 can be replaced by a bus.

A NOC can span synchronous and asynchronous clock domains or use un-clocked asynchronous logic. NOC technology applies networking theory and methods to on-chip communications and brings notable improvements over conventional bus and crossbar interconnections. NOC improves the scalability of systems on a chip (SoC) and the power efficiency of complex SoCs compared to other designs.

In embodiments, the wires and the links of a NOC are shared by many signals. A high level of parallelism is achieved because all links in the NOC can operate simultaneously on different data packets. Therefore, as the complexity of integrated subsystems keep growing, a NOC provides enhanced performance (such as throughput) and scalability in comparison with previous communication architectures (e.g., dedicated point-to-point signal wires, shared buses, or segmented buses with bridges).

Connected to and in communication with NOC 112 is processor 114, ECC engine 116, memory interface 118, and DRAM controller 120. DRAM controller 120 is used to operate and communicate with local high speed volatile memory 108 (e.g., DRAM). In other embodiments, local high speed volatile memory 108 can be SRAM or another type of volatile memory.

ECC engine 116 performs error correction services. For example, ECC engine 116 performs data encoding and decoding, as per the implemented ECC technique. In one embodiment, ECC engine 116 is an electrical circuit programmed by software. For example, ECC engine 116 can be a processor that can be programmed. In other embodiments, ECC engine 116 is a custom and dedicated hardware circuit without any software. In another embodiment, the function of ECC engine 116 is implemented by processor 114.

Processor 114 performs the various controller memory operations, such as programming, erasing, reading, as well as memory management processes. In an embodiment, processor 114 is programmed by firmware. In other embodiments, processor 114 is a custom and dedicated hardware circuit without any software. In an embodiment, processor 114 also implements a translation module, as a software/firmware process or as a dedicated hardware circuit.

In many systems, non-volatile memory is addressed internally to the storage system using physical addresses associated with the one or more memory die. However, the host system will use logical addresses to address the various memory locations. This enables the host to assign data to consecutive logical addresses, while the storage system is free to store the data as it wishes among the locations of the one or more memory die. To enable this system, the controller (e.g., the translation module) performs address translation between the logical addresses used by the host and the physical addresses used by the memory dies.

One example implementation is to maintain tables (e.g., the L2P tables mentioned above) that identify a translation between logical addresses and physical addresses. An entry in the L2P table may include an identification of a logical address and corresponding physical address. Although logical address to physical address tables (or L2P tables) include the word “tables” they need not literally be tables. Rather, the logical address to physical address tables (or L2P tables) can be any type of data structure.

In some examples, the memory space of a storage system is so large that local memory 108 cannot hold all of the L2P tables. In such a case, the entire set of L2P tables are stored in a memory die 106 and a subset of the L2P tables are cached (L2P cache) in the local high speed volatile memory 108.

In an embodiment, memory interface 118 communicates with one or more memory die 106. In an embodiment, memory interface 118 provides a Toggle Mode interface. Other interfaces also can be used. In some example implementations, memory interface 118 (or another portion of controller 104) implements a scheduler and buffer for transmitting data to and receiving data from one or more memory die.

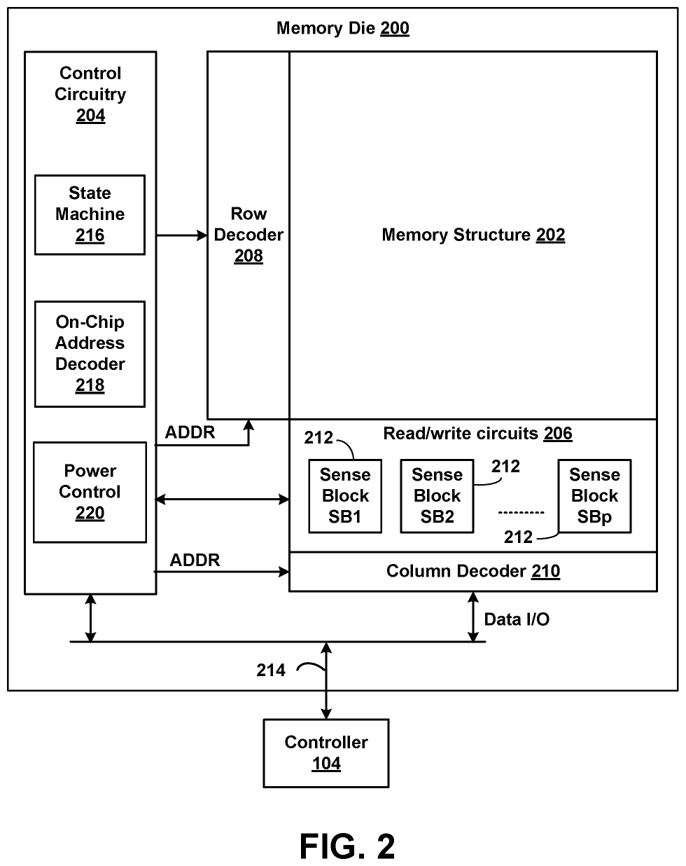

FIG. 2 is a functional block diagram of one embodiment of a memory die 200. Each of the one or more memory die 106 of FIG. 1 can be implemented as memory die 200 of FIG. 2. The components depicted in FIG. 2 are electrical circuits. In an embodiment, each memory die 200 includes a memory structure 202, control circuitry 204, and read/write circuits 206. Memory structure 202 is addressable by word lines via a row decoder 208 and by bit lines via a column decoder 210.

In an embodiment, read/write circuits 206 include multiple sense blocks 212 including SB1, SB2, . . . , SBp (sensing circuitry) and allow a page (or multiple pages) of data in multiple memory cells to be read or programmed (written) in parallel. In an embodiment, each sense block 212 include a sense amplifier and a set of latches connected to the bit line. The latches store data to be written and/or data that has been read. In an embodiment, each sense amplifier 212 includes bit line drivers. In an embodiment, commands and data are transferred between controller 104 and memory die 200 via lines 214. In an embodiment, memory die 200 includes a set of input and/or output (I/O) pins that connect to lines 214.

In an embodiment, control circuitry 204 cooperates with read/write circuits 206 to perform memory operations (e.g., write, read, erase, and others) on memory structure 202. In an embodiment, control circuitry 204 includes a state machine 216, an on-chip address decoder 218, and a power control circuit 220. In an embodiment, state machine 216 provides die-level control of memory operations. In an embodiment, state machine 216 is programmable by software. In other embodiments, state machine 216 does not use software and is completely implemented in hardware (e.g., electrical circuits). In some embodiments, state machine 216 can be replaced by a microcontroller or microprocessor. In an embodiment, control circuitry 204 includes buffers such as registers, ROM fuses and other storage devices for storing default values such as base voltages and other parameters.

On-chip address decoder 218 provides an address interface between addresses used by controller 104 to the hardware address used by row decoder 208 and column decoder 210. Power control module 220 controls the power and voltages supplied to the word lines and bit lines during memory operations. Power control module 220 may include charge pumps for creating voltages.

For purposes of this document, control circuitry 204, read/write circuits 206, row decoder 208 and column decoder 210 comprise a control circuit for memory structure 202. In other embodiments, other circuits that support and operate on memory structure 202 can be referred to as a control circuit. For example, in some embodiments, controller 104 can operate as the control circuit or can be part of the control circuit. The control circuit also can be implemented as a microprocessor or other type of processor that is hardwired or programmed to perform the functions described herein.

For purposes of this document, control circuitry 204, read/write circuits 206, row decoder 208 and column decoder 210 comprise peripheral circuits for memory structure 202, as they are not part of memory structure 202 but are on the same die as memory structure 202 and are used to operate memory structure 202.

In an embodiment, memory structure 202 is a three dimensional memory array of non-volatile memory cells. In an embodiment, memory structure 202 is a monolithic three dimensional memory array in which multiple memory levels are formed above a single substrate, such as a wafer. The memory structure may be any type of non-volatile memory that is formed in one or more physical levels of arrays of memory cells having an active area disposed above a silicon (or other type of) substrate. In one example, the non-volatile memory cells of memory structure 202 include vertical NAND strings with charge-trapping material such as described. A NAND string includes memory cells connected by a channel.

In another embodiment, memory structure 202 includes a two dimensional memory array of non-volatile memory cells. In an example, the non-volatile memory cells are NAND flash memory cells utilizing floating gates. Other types of memory cells (e.g., NOR-type flash memory) also can be used.

The exact type of memory array architecture or memory cell included in memory structure 202 is not limited to the examples above. Many different types of memory array architectures or memory cell technologies can be used to form memory structure 202. No particular non-volatile memory technology is required for purposes of the new technology described herein.

Other examples of suitable technologies for memory cells of the memory structure 202 include ReRAM memories, magnetoresistive memory (MRAM), phase change memory (PCM), and the like. Examples of suitable technologies for architectures of memory structure 202 include two dimensional arrays, three dimensional arrays, cross-point arrays, stacked two dimensional arrays, vertical bit line arrays, and the like.

One example of a cross point memory includes reversible resistance-switching elements arranged in cross point arrays accessed by X lines and Y lines (e.g., word lines and bit lines). In another embodiment, the memory cells may include conductive bridge memory elements. A conductive bridge memory element also may be referred to as a programmable metallization cell.

A conductive bridge memory element may be used as a state change element based on the physical relocation of ions within a solid electrolyte. In some cases, a conductive bridge memory element may include two solid metal electrodes, one relatively inert (e.g., tungsten) and the other electrochemically active (e.g., silver or copper), with a thin film of solid electrolyte between the two electrodes.

MRAM stores data using magnetic storage elements. The magnetic storage elements are formed from two ferromagnetic plates, each of which can hold a magnetization, separated by a thin insulating layer. One of the two plates is a permanent magnet set to a particular polarity; the other plate's magnetization can be changed to match that of an external field to store memory. A memory device is built from a grid of such memory cells. In one embodiment for programming, each memory cell lies between a pair of write lines arranged at right angles to each other, parallel to the cell, one above and one below the cell. When current is passed through them, an induced magnetic field is created.

Phase change memory (PCM) exploits the unique behavior of chalcogenide glass. One embodiment uses a GeTe−Sb₂Te₃ super lattice to achieve non-thermal phase changes by simply changing the coordination state of Germanium atoms with a laser pulse (or light pulse from another source). Therefore, the doses of programming are laser pulses. The memory cells can be inhibited from programming by blocking the memory cells from receiving the light.

A person of ordinary skill in the art will recognize that the technology described herein is not limited to a single specific memory structure, but covers many relevant memory structures within the scope of the technology as described herein and as understood by one of ordinary skill in the art.

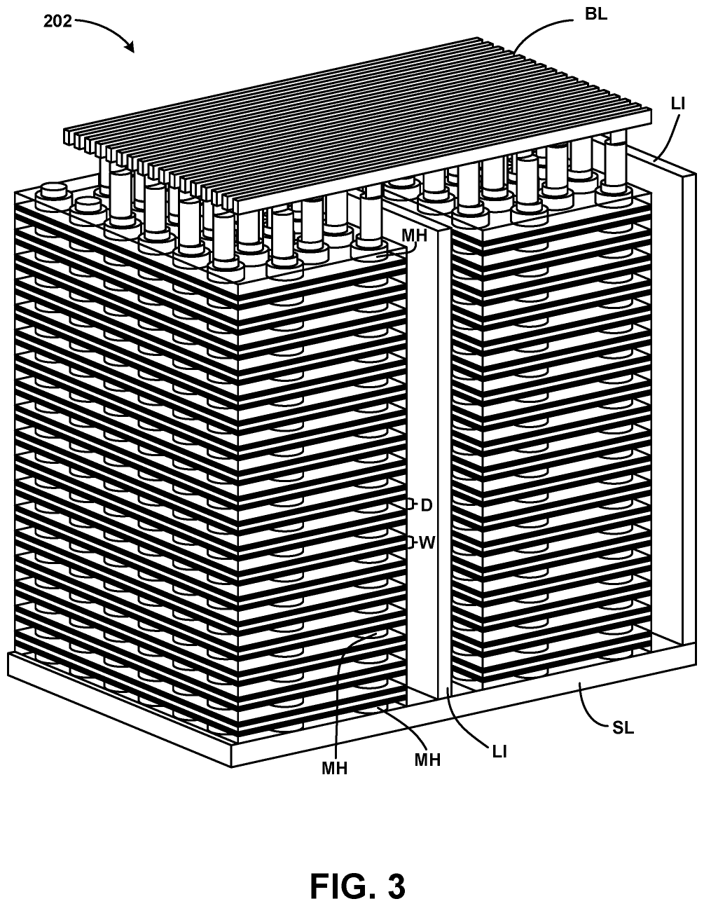

FIG. 3 is a perspective view of a portion of an embodiment of a three dimensional memory array that includes memory structure 202. In an embodiment, memory structure 202 includes multiple non-volatile memory cells. For example, FIG. 3 shows a portion of one block of memory cells. The structure depicted includes a set of bit lines BL positioned above a stack of alternating dielectric layers and conductive layers. For example purposes, one of the dielectric layers is marked as D and one of the conductive layers (also called word line layers) is marked as W.

The number of alternating dielectric layers and conductive layers can vary based on specific implementation requirements. One set of embodiments includes between 108-300 alternating dielectric layers and conductive layers. One example embodiment includes 96 data word line layers, 8 select layers, 6 dummy word line layers and 110 dielectric layers. More or less than 108-300 layers also can be used. In an embodiment, the alternating dielectric layers and conductive layers are divided into four regions by local interconnects LI. FIG. 3 shows two regions and two local interconnects LI.

A source line layer SL is below the alternating dielectric layers and word line layers. Memory holes are formed in the stack of alternating dielectric layers and conductive layers. For example, one of the memory holes is marked as MH. Note that in FIG. 3 the dielectric layers are depicted as see-through so that the reader can see the memory holes positioned in the stack of alternating dielectric layers and conductive layers.

In an embodiment, NAND strings are formed by filling the memory hole with materials including a charge-trapping material to create a vertical column of memory cells (also referred to as a memory column). In an embodiment, each memory cell can store one or more bits of data. In an embodiment, each memory hole MH is associated with and coupled to a corresponding one of bit lines BL. In an embodiment, each bit line BL is coupled to one or more memory holes MH. More details of a three dimensional memory array that comprises memory structure 202 are described below.

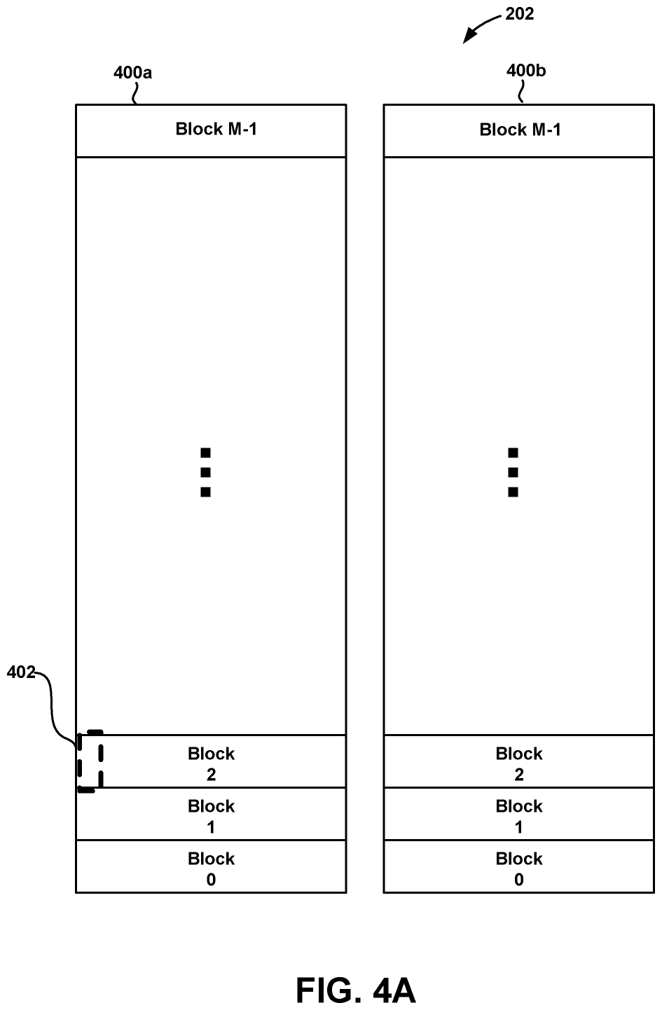

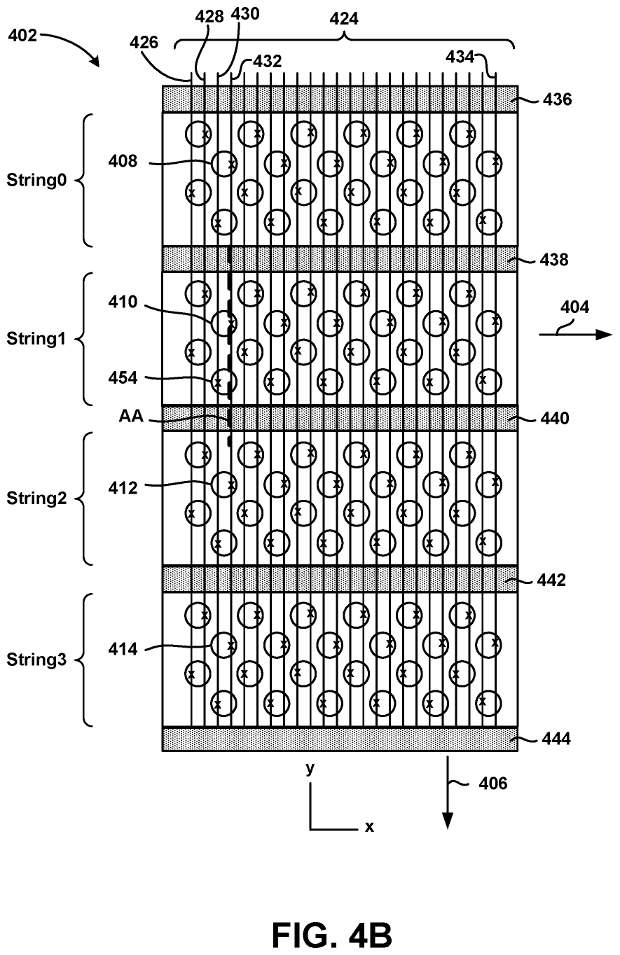

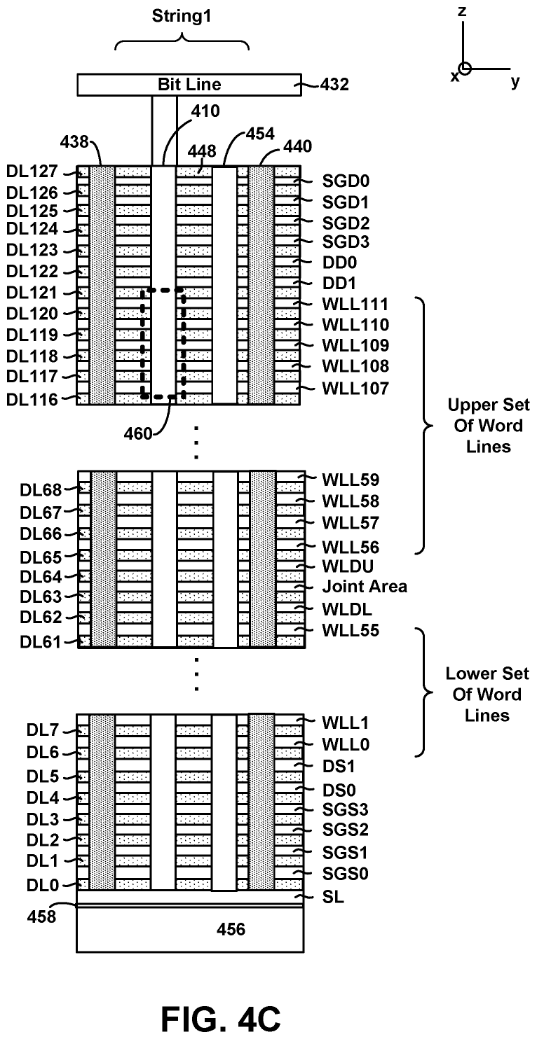

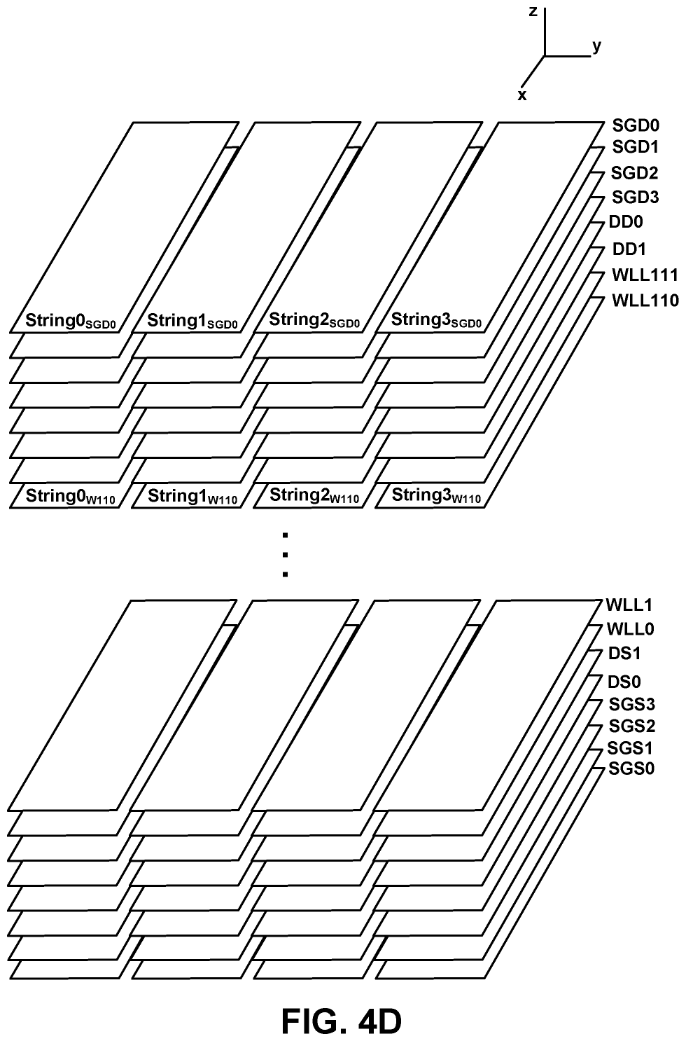

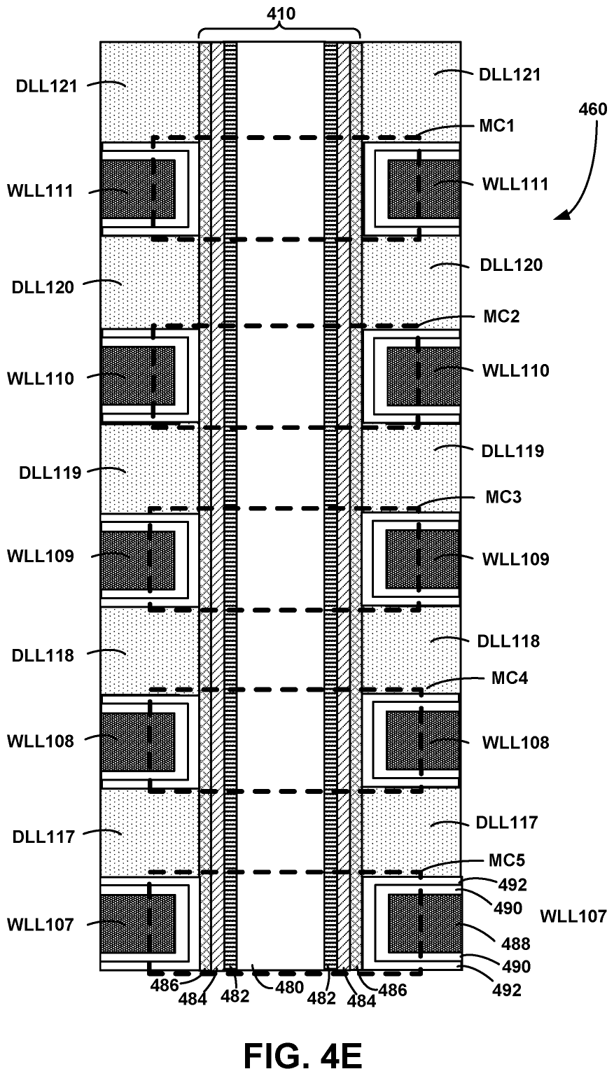

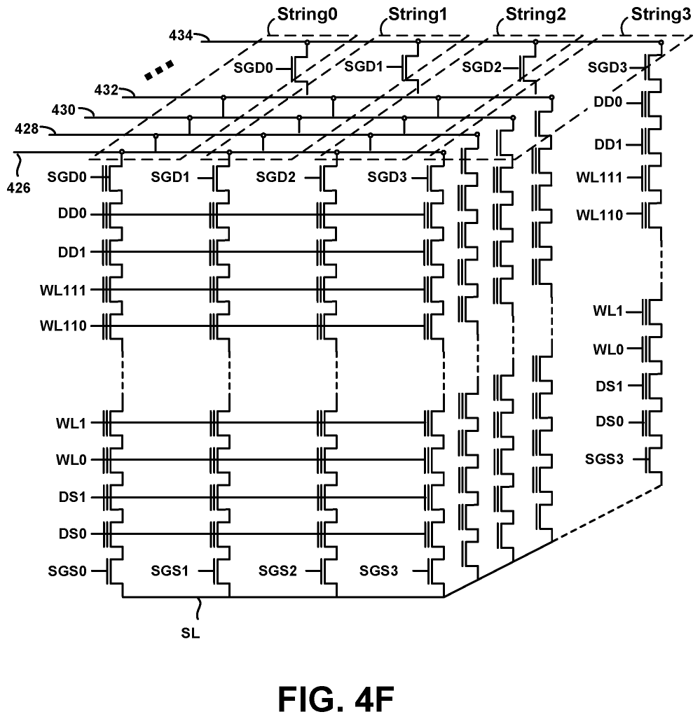

FIG. 4A is a block diagram explaining one example organization of memory structure 202, which is divided into two planes 400a and 400b. Both planes are on the same memory die 200 (FIG. 2). Each plane is then divided into M blocks. In one example, each plane has about 2000 blocks. However, different numbers of blocks and planes also can be used. A portion 402 of block 2 of memory plane 400a is shown in dashed line in FIG. 4A.

In an embodiment, a block of memory cells is a unit of erase. That is, all memory cells of a block are erased together. In other embodiments, memory cells can be grouped into blocks for other reasons, such as to organize memory structure 202 to enable the signaling and selection circuits. In some embodiments, a block represents a group of connected memory cells as the memory cells of a block share a common set of word lines. Although FIG. 4A shows two planes on the same die, in other embodiments more than two planes can be implemented. For example, memory structure 202 can include 2-8 (or more) planes.

FIGS. 4B-4F depict an example three dimensional (“3D”) NAND structure that corresponds to the structure of FIG. 3. FIG. 4B is a block diagram depicting a top view of portion 402 (FIG. 4A) of memory structure 202. As can be seen from FIG. 4B, portion 402 extends in direction 404 and direction 406. In an embodiment, the memory array has many layers, however, FIG. 4B only shows the top layer.

FIG. 4B depicts a plurality of circles that represent the memory holes, which are also referred to as memory columns. For example, FIG. 4B depicts memory holes 408, 410, 412 and 414. Each of the memory holes include multiple select transistors (also referred to as a select gate or selection gate) and multiple memory cells. In an embodiment, each memory hole implements a NAND string. Because portion 402 extends in directions 404 and 406, the block includes more memory holes than depicted in FIG. 4B.

FIG. 4B also depicts a set of bit lines 424, including bit lines 426, 428, 430, 432, 434. In an embodiment, each memory hole is associated with and coupled to a corresponding one of the bit lines. In an embodiment, each bit line is coupled to one or more memory holes. FIG. 4B shows twenty four bit lines because only a portion of the block is depicted. It is contemplated that more than twenty four bit lines are connected to memory holes of the block. Each of the circles representing a memory hole has an “x” to indicate its connection to one bit line. For example, bit line 432 is connected to memory holes 408, 410, 412 and 414.

Portion 402 depicted in FIG. 4B includes a set of local interconnects 436, 438, 440, 442 and 444 that connect the various layers to a source line below the memory holes. Local interconnects 436, 438, 440, 442 and 444 also serve to divide each layer of the block into four regions. For example, the top layer depicted in FIG. 4B is divided into four regions designated as String0, String1, Sting2 and String3. In the layers of the block that implement memory cells, String0, String1, Sting2 and String3 also may be referred to as word line fingers that are separated by the local interconnects.

In an embodiment, the word line fingers on a common level of a block connect together to form a single word line. In another embodiment, the word line fingers on the same level are not connected together. In an example implementation, a bit line connects to a single memory hole in each of String0, String1, Sting2 and String3. In that implementation, each block has sixteen rows of active columns and each bit line connects to four rows in each block.

In an embodiment, all four rows connected to a common bit line are connected to the same word line (via different word line fingers on the same level that are connected together). Therefore, the system uses the source side selection lines and the drain side selection lines to choose one (or another subset) of the four to be subjected to a memory operation (program, verify, read, and/or erase).

Although FIG. 4B shows four regions String0, String1, Sting2 and String3, each having four rows of memory holes, and sixteen rows of memory holes in a block, those exact numbers are an example implementation. Other embodiments may include more or less regions per block, more or less rows of memory holes per region and more or less rows of memory holes per block. FIG. 4B also shows the memory holes being staggered. In other embodiments, different patterns of staggering can be used. In some embodiments, the memory holes are not staggered.

FIG. 4C depicts a portion of one embodiment of a three dimensional memory structure 202 showing a cross-sectional view along line AA of FIG. 4B. This cross sectional view cuts through memory holes 410 and 454 of String1 (see FIG. 4B). The structure of FIG. 4C includes four drain side select layers SGD0, SGD1, SGD2 and SGD3, four source side select layers SGS0, SGS1, SGS2 and SGS3, six dummy word line layers DD0, DD1, DS0, DS1, WLDL, WLDU, and one hundred and twelve data word line layers WLL0-WLL111 for connecting to memory cells. Other embodiments can implement more or less than four drain side select layers, more or less than four source side select layers, more or less than six dummy word line layers, and more or less than one hundred and twelve word lines.

Memory holes 410 and 454 are depicted protruding through the drain side select layers, source side select layers, dummy word line layers and word line layers. In one embodiment, each memory hole includes a vertical NAND string. Below the memory holes and the layers listed below is substrate 456, an insulating film 458 on the substrate, and source line SL. The NAND string of memory hole 410 has a source end at a bottom of the stack and a drain end at a top of the stack. As in agreement with FIG. 4B, FIG. 4C shows memory hole 410 connected to bit line 432 via connector 460. Local interconnects 438 and 440 also are depicted.

For ease of reference, drain side select layers SGD0, SGD1, SGD2 and SGD3, source side select layers SGS0, SGS1, SGS2 and SGS3, dummy word line layers DD0, DD1, DS0, DS1, WLDL and WLDU, and word line layers WLL0-WLL111 collectively are referred to as the conductive layers. In an embodiment, the conductive layers are made from a combination of TiN and tungsten. In other embodiments, other materials can be used to form the conductive layers, such as doped polysilicon, metal such as tungsten or metal silicide. In some embodiments, different conductive layers can be formed from different materials.

Between conductive layers are dielectric layers DL0-DL127. For example, dielectric layer DL120 is above word line layer WLL110 and below word line layer WLL111. In an embodiment, the dielectric layers are made from SiO₂. In other embodiments, other dielectric materials can be used to form the dielectric layers.

The non-volatile memory cells are formed along memory holes which extend through alternating conductive and dielectric layers in the stack. In an embodiment, the memory cells are arranged in NAND strings. The word line layers WLL0-WLL111 connect to memory cells (also called data memory cells). Dummy word line layers DD0, DD1, DS0, DS1, WLDL and WLDU connect to dummy memory cells. A dummy memory cell does not store and is not eligible to store host data (data provided from the host, such as data from a user of the host), while a data memory cell is eligible to store host data.

In some embodiments, data memory cells and dummy memory cells may have a same structure. A dummy word line is connected to dummy memory cells. Drain side select layers SGD0, SGD1, SGD2 and SGD3 are used to electrically connect and disconnect NAND strings from bit lines. Source side select layers SGS0, SGS1, SGS2 and SGS3 are used to electrically connect and disconnect NAND strings from the source line SL.

FIG. 4C also shows a “Joint Area.” In an embodiment it is expensive and/or challenging to etch one hundred and twelve word line layers intermixed with dielectric layers. To ease this burden, one embodiment includes laying down a first stack of fifty-six word line layers alternating with dielectric layers, laying down the Joint Area, and laying down a second stack of fifty-six word line layers alternating with dielectric layers. The Joint Area is positioned between the first stack and the second stack. The Joint Area is used to connect the first stack to the second stack.

In FIG. 4C, the first stack is labeled as the “Lower Set of Word Lines” and the second stack is labeled as the “Upper Set of Word Lines.” In an embodiment, the Joint Area is made from the same materials as the word line layers. In one example set of implementations, the plurality of word lines (control lines) comprises a first stack of alternating word line layers and dielectric layers, a second stack of alternating word line layers and dielectric layers, and a joint area between the first stack and the second stack, as depicted in FIG. 4C.

FIG. 4D depicts a logical representation of the conductive layers (SGD0, SGD1, SGD2, SGD3, SGS0, SGS1, SGS2, SGS3, DD0, DD1, DS0, DS1, and WLL0-WLL111) for the block that is partially depicted in FIG. 4C. As mentioned above with respect to FIG. 4B, in an embodiment local interconnects 436, 438, 440, 442 and 444 break up the conductive layers into four regions/fingers.

For example, word line layer WLL110 is divided into regions String0_{W110}, String1_{W110}, String2_{W110} and String3_{W110}. In an embodiment, the four word line fingers on a same level are connected together. In another embodiment, each word line finger operates as a separate word line.

Likewise, drain side select gate layer SGD0 (the top layer) is divided into regions Strin0_{SGD0}, String1_{SGD0}, String2_{SGD0} and String3_{SGD0}, also known as fingers or select line fingers. In an embodiment, the four select line fingers on a same level are connected together. In another embodiment, each select line finger operates as a separate word line.

FIG. 4E depicts a cross sectional view of String1 of FIG. 4C that includes a portion of memory hole 410. In an embodiment, the memory holes (e.g., memory hole 410) are shaped as cylinders. In other embodiment, however, memory holes may have other shapes. In an embodiment, memory hole 410 includes an inner core layer 480, a channel 482 surrounding inner core layer 480, a tunneling dielectric 484 surrounding channel 482, and a charge trapping layer 486 surrounding tunneling dielectric 484. In an embodiment, inner core layer 480 a dielectric material (e.g., SiO₂), channel 482 is polysilicon, tunneling dielectric 484 has an ONO structure, and charge trapping layer 486 is silicon nitride. Other memory materials and structures can also be used. The technology described herein is not limited to any particular material or structure.

FIG. 4E depicts dielectric layers DLL121, DLL120, DLL119, DLL118 and DLL117, as well as word line layers WLL107, WLL108, WLL109, WLL110, and WLL111. In an embodiment, each of the word line layers includes a word line region 488 surrounded by an aluminum oxide layer 490, which is surrounded by a blocking oxide (SiO₂) layer 492. The physical interaction of the word line layers with the memory hole forms the memory cells. Thus, a memory cell, in an embodiment, includes channel 482, tunneling dielectric 484, charge trapping layer 486, blocking oxide layer 492, aluminum oxide layer 490 and word line region 488.

For example, word line layer WLL111 and a portion of memory hole 410 comprise a memory cell MC1. Word line layer WLL110 and a portion of memory hole 410 comprise a memory cell MC2. Word line layer WLL109 and a portion of memory hole 410 comprise a memory cell MC3. Word line layer WLL108 and a portion of memory hole 410 comprise a memory cell MC4. Word line layer WLL107 and a portion of memory hole 410 comprise a memory cell MC5. In other architectures, a memory cell may have a different structure; however, the memory cell would still be the storage unit.

In an embodiment, when a memory cell is programmed, electrons are stored in a portion of the charge trapping layer 486 which is associated with the memory cell. These electrons are drawn into the charge trapping layer 486 from the channel 482, through the tunneling dielectric 484, in response to an appropriate voltage on word line region 488. The threshold voltage of a memory cell is increased in proportion to the amount of stored charge.

In an embodiment, programming a memory cell is achieved through Fowler-Nordheim tunneling of the electrons into charge trapping layer 486. During an erase operation, the electrons return to channel 482 or holes are injected into charge trapping layer 486 to recombine with electrons. In an embodiment, erasing is achieved using hole injection into charge trapping layer 486 via a physical mechanism such as gate induced drain leakage (GIDL). In another erase technique, erase pulses are applied to the substrate, causing holes to be injected into the channels via the source ends of the NAND strings.

FIG. 4F is a schematic diagram of corresponding to portion 402 in Block 2 of FIGS. 4A-E, including bit lines 426, 428, 430, 432, . . . 434, and word lines WLL0-WLL111. Within the block, each bit line is connected to four NAND strings. Drain side selection lines SGD0, SGD1, SGD2 and SGD3 are used to determine which of the four NAND strings connect to the associated bit line(s). Source side selection lines SGS0, SGS1, SGS2 and SGS3 are used to determine which of the four NAND strings connect to the common source line.

During any given memory operation, a subset of the memory cells will be identified to be subjected to one or more parts of the memory operation. These memory cells identified to be subjected to the memory operation are referred to as selected memory cells. Memory cells that have not been identified to be subjected to the memory operation are referred to as unselected memory cells. Depending on the memory architecture, the memory type, and the memory operation, unselected memory cells may be actively or passively excluded from being subjected to the memory operation.

During a memory operation some word lines are referred to as selected word lines because they are connected to selected memory cells. Unselected word lines are not connected to selected memory cells. Similarly, selected bit lines are connected to selected memory cells and unselected bit lines are not connected to selected memory cells.

Although the example memory system of FIG. 3 and FIGS. 4A-4F is a three dimensional memory structure that includes vertical NAND strings with charge-trapping material, other (2D and 3D) memory structures also can be used with the technology described herein.

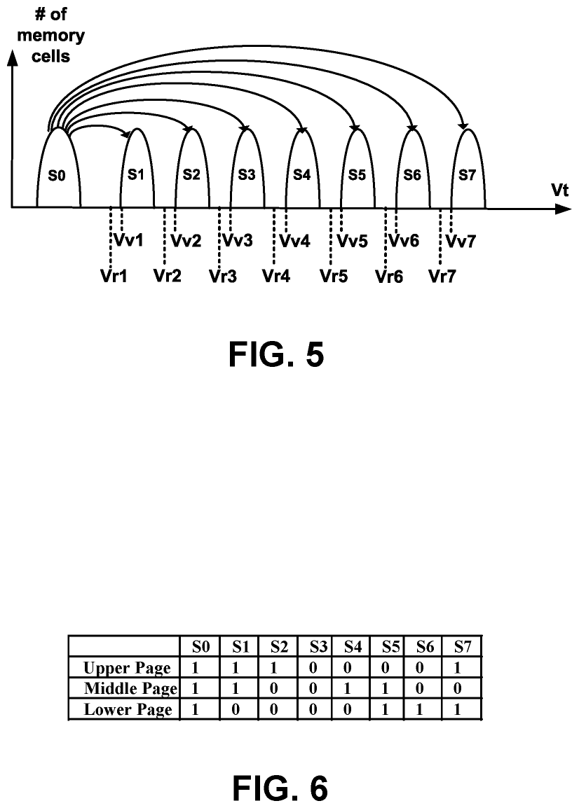

The memory systems discussed above can be erased, programmed and read. At the end of a successful programming process (with verification), the threshold voltages of the memory cells should be within one or more distributions of threshold voltages for programmed memory cells or within a distribution of threshold voltages for erased memory cells, as appropriate. FIG. 5 illustrates example threshold voltage distributions for a memory array when each memory cell stores three bits of data. Other embodiments, however, may use other data capacities per memory cell (e.g., such as one, two, four, or five bits of data per memory cell).

FIG. 5 shows eight threshold voltage distributions, corresponding to eight data states. The first threshold voltage distribution (data state) S0 represents memory cells that are erased. The other seven threshold voltage distributions (data states) S1-S7 represent memory cells that are programmed and, therefore, are also called programmed states.

Each threshold voltage distribution (data state) corresponds to predetermined values for the set of data bits. The specific relationship between the data programmed into a memory cell and the threshold voltage levels of the memory cell depends on the data encoding scheme adopted for the cells. In an embodiment, data values are assigned to the threshold voltage ranges using a Gray code assignment so that if the threshold voltage of a memory cell erroneously shifts to its neighboring physical state, only one bit will be affected.

FIG. 5 shows seven read reference voltages, Vr1, Vr2, Vr3, Vr4, Vr5, Vr6, and Vr7 for reading data from memory cells. By testing (e.g., performing sense operations) whether the threshold voltage of a given memory cell is above or below the seven read reference voltages, the system can determine what data state (S0, S1, S2, S3, . . . , S7) a memory cell is in.

FIG. 5 also shows seven verify reference voltages, Vv1, Vv2, Vv3, Vv4, Vv5, Vv6, and Vv7. When programming memory cells to data states S1, S2, S3, S4, S5, S6 and S7, the system will test whether those memory cells have a threshold voltage greater than or equal to Vv1, Vv2, Vv3, Vv4, Vv5, Vv6 and Vv7, respectively.

In an embodiment, known as full sequence programming, memory cells can be programmed from the erased data state S0 directly to any of the programmed states S1-S7. For example, a population of memory cells to be programmed may first be erased so that all memory cells in the population are in erased data state S0. Then, a programming process is used to program memory cells directly into data states S1, S2, S3, S4, S5, S6, and/or S7. For example, while some memory cells are being programmed from data state S0 to data state S1, other memory cells are being programmed from data state S0 to data state S2 and/or from data state S0 to data state S3, and so on. The arrows of FIG. 5 represent full sequence programming.

The technology described herein also can be used with other types of programming in addition to full sequence programming (including, but not limited to, multiple stage/phase programming). In some embodiments, programmed states S1-S7 can overlap, with controller 104 (FIG. 1) relying on error correction to identify the correct data being stored.

FIG. 6 is a table describing an example assignment of data values to data states. In the table of FIG. 6, S0=111, S1=110, S2=100, S3=000, S4=010, S5=011, S6=001 and S7=101. Other encodings of data also can be used. No particular data encoding is required by the technology disclosed herein. In an embodiment, when a block is subjected to an erase operation, all memory cells are moved to data state S0, the erased state. In the embodiment of FIG. 6, all bits stored in a memory cell are “1” when the memory cell is erased (e.g., in data state S0).

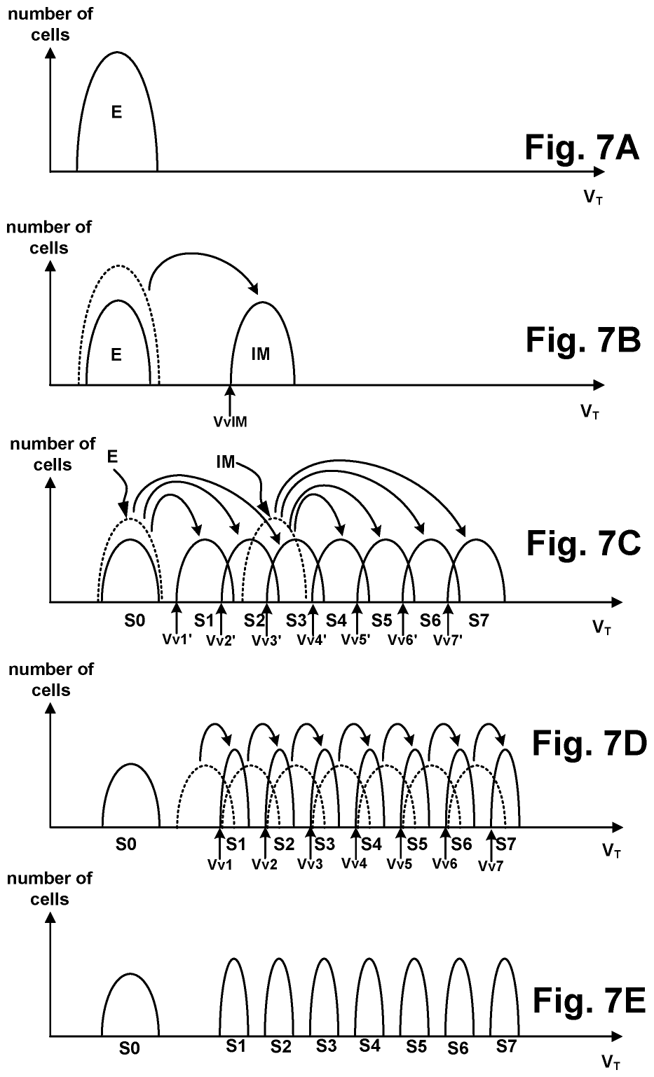

FIGS. 7A-7E illustrate a multi-phase programming approach. In this embodiment, the programming process includes three phases. Prior to programming, the memory cells are erased so that all memory cells connected to a common word line are in an erased threshold voltage distribution E, as depicted in FIG. 7A.

During the first programming phase, those memory cells whose targets (due to the data to be stored in those memory cells) are data states S4, S5, S6 or S7 are programmed to an intermediate threshold voltage distribution IM. Those memory cells are targeted for data states S0, S1, S2 or S3 remain in the erased threshold voltage distribution E. The first phase is graphically depicted in FIG. 7B. Memory cells being programmed to intermediate threshold voltage distribution IM are programmed to a target threshold voltage of VvIM.

During the second programming phase, those memory cells that are in the erased threshold voltage distribution E are programmed to their target data states. For example, those memory cells to be programmed to data state S3 are programmed from erased threshold voltage distribution E to data state S3, those memory cells to be programmed to data state S2 are programmed from erased threshold voltage distribution E to data state S2, those memory cells to be programmed to data state S1 are programmed from erase threshold voltage distribution E to data state S1, and those memory cells to be in data state S0 are not programmed during the second phase of the programming process. Thus, erased threshold voltage distribution E becomes data state S0.

Also, during the second programming phase, those memory cells that are in the intermediate state threshold voltage distribution IM are programmed to their target data states. For example, those memory cells to be programmed to data state S7 are programmed from intermediate threshold voltage distribution IM to data state S7, those memory cells to be programmed to data state S6 are programmed from intermediate threshold voltage distribution IM to data state S6, those memory cells to be programmed to data state S5 are programmed from intermediate threshold voltage distribution IM to data state S5, and those memory cells to be in data state S4 are programmed from intermediate threshold voltage distribution IM to data state S4. This second programming phase is illustrated in FIG. 7C.

As can be seen in FIG. 7C, at the end of the second programming phase data states S1-S7 overlap with neighboring data states. For example, data state S1 overlaps with data state S2, data state S2 overlaps with data states S1 and S3, data state S3 overlaps with data states S2 and S4, data state S4 overlaps with data states S3 and S5, data state S5 overlaps with data states S4 and S6, and data state S6 overlaps with data states S5 and S7. In some embodiments, all or some of the data states do not overlap.

In the third programming phase, each of data states S1-S7 are tightened so that they no longer overlap with neighboring states. This is depicted graphically by FIG. 7D. The final result of the three phrase programming process is depicted in FIG. 7E, which shows data states S0-S7. In some embodiments, data state S0 is wider than data states S1-S7. In an embodiment, the data states of FIGS. 7A-7E may be encoded according to the table of FIG. 6.

In some embodiments, those memory cells to be programmed to data state S4 are not programmed during the second phase and, therefore, remain in intermediate threshold voltage distribution IM. During the third programming phase, the memory cells are programmed from intermediate threshold voltage distribution IM to S4. In other embodiments, memory cells destined for other states can also remain in intermediate threshold voltage distribution IM or erase threshold voltage distribution E during the second phase.

A programming operation for a set of memory cells typically involves applying a series of program voltage pulses to the memory cells after the memory cells are provided in an erased state. For example, the program voltage pulses may be applied to a word line which is connected to control gates of the memory cells.

In one approach, incremental step pulse programming (ISPP) is performed, where the program voltage pulse amplitude is sequentially increased by a step size. Verify operations may be performed after each program voltage pulse to determine whether the memory cells have completed programming. When programming is completed for a memory cell, the memory cell can be locked out from further programming while programming continues for other memory cells.

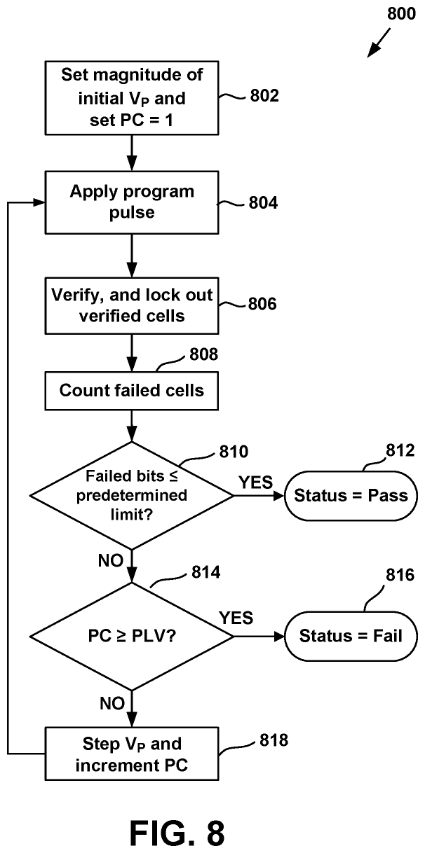

FIG. 8 is a flowchart describing an embodiment of a process 800 for programming a memory cell. In an example embodiment, process 800 is performed on memory die 106 (FIG. 1) using the control circuits discussed above. For example, process 800 can be performed at the direction of state machine 216 (FIG. 2). Process 800 also can be used to implement the full sequence programming discussed above. Additionally, process 800 can be used to implement each phase of a multi-phase programming process.

In step 802 of process 800, a programming voltage (V_{P}) is initialized to a starting program voltage V_{Pinit} (e.g., between about 12V to about 16V, or some other value) and a program counter PC maintained by state machine 216 is initialized at 1.

In step 804, a program pulse having a magnitude V_{P} is applied to the selected word line (the word line selected for programming). In an embodiment, the group of memory cells being concurrently programmed are all connected to the same word line (the selected word line). If a memory cell is to be programmed, then the corresponding bit line coupled to the memory cell is grounded.

If a memory cell should remain at its current threshold voltage, then the corresponding bit line coupled to the memory cell is connected to Vdd to inhibit programming. In an embodiment, the unselected word lines receive one or more boosting voltages (e.g., between about 7V to about 11V, or some other value) to perform boosting schemes known in the art.

In step 804, the program pulse is applied to all memory cells connected to the selected word line so that all of the connected memory cells are programmed concurrently. That is, they are programmed at the same time or during overlapping times (both of which are considered concurrent). In this manner all of the memory cells connected to the selected word line will concurrently have their threshold voltage change, unless they have been locked out from programming.

In step 806, the memory cells are verified using the appropriate set of verify reference voltages to perform one or more verify operations. In an embodiment, the verification process is performed by testing whether the threshold voltages of the memory cells selected for programming have reached the appropriate verify reference voltage.

In step 808, the memory system counts the number of memory cells that have not yet reached their respective target threshold voltage distribution. That is, the system counts the number of memory cells that have so far failed the verify process. This counting can be done by state machine 216 (FIG. 2), controller 104 (FIG. 1), or other logic. In the remaining discussion, the term “Controller Device” may be one or more of controller 104 of FIG. 1, control circuitry 204 of FIG. 2, state machine 216 of FIG. 2, or other similar controller device.

In an embodiment, each of sense blocks 212 (FIG. 2) stores the status (pass/fail) of their respective memory cells. In an embodiment, one total count reflects the total number of memory cells currently being programmed that have failed the last verify step. In another embodiment, separate counts are kept for each data state.

In step 810, a determination is made whether the count from step 808 is less than or equal to a predetermined limit. In an embodiment, the predetermined limit is the number of bits that can be corrected by error correction codes (ECC) during a read process for the page of memory cells. If the number of failed cells is less than or equal to the predetermined limit, than the programming process can stop and a status of “PASS” is reported in step 812. In this situation, enough memory cells programmed correctly such that the few remaining memory cells that have not been completely programmed can be corrected using ECC during the read process.

In some embodiments, the predetermined limit used in step 810 is below the number of bits that can be corrected by error correction codes (ECC) during a read process to allow for future/additional errors. When programming less than all of the memory cells for a page, or comparing a count for only one data state (or less than all states), then the predetermined limit can be a portion (pro-rata or not pro-rata) of the number of bits that can be corrected by ECC during a read process for the page of memory cells. In some embodiments, the limit is not predetermined. Instead, the limit changes based on the number of errors already counted for the page, the number of program-erase cycles performed or other criteria.

If the number of failed memory cells is not less than the predetermined limit, then the programming process continues at step 814 and the program counter PC is checked against a program limit value (PLV). Examples of program limit values include 6, 12, 16, 20 and 30, although other values can be used. If the program counter PC is greater than or equal to program limit value PLV, then the program process is considered to have failed and a status of FAIL is reported in step 816.

If the program counter PC is not greater than or equal to program limit value PLV, then the process continues at step 820 in which the Program Counter PC is incremented by 1 and program voltage V_{P} is stepped up to the next magnitude. For example, the next program pulse will have a magnitude greater than the previous pulse by a program step size ΔV_{P} (e.g., a step size of between about 0.1V to about 1.0V, or some other value). The process loops back to step 804 and another program pulse is applied to the selected word line so that another iteration (steps 804-818) of programming process 800 is performed. Each pass through steps 804-818 is referred to herein as a “program loop.”

In general, during verify operations and read operations, the selected word line is connected to a voltage (one example of a reference signal), a level of which is specified for each read operation (e.g., read compare levels Vr1, Vr2, Vr3, Vr4, Vr5, Vr6, and Vr7, of FIG. 5) or verify operation (e.g. verify target levels Vv1, Vv2, Vv3, Vv4, Vv5, Vv6, and Vv7 of FIG. 5) to determine whether a threshold voltage of the selected memory cell has reached such level.

In an embodiment, after an appropriate read or verify voltage is applied to a selected word line, a conduction current of the memory cell is measured to determine whether the memory cell turned ON (conducts current) in response to the voltage applied to the word line. If the conduction current is measured to be greater than a certain value, then it is assumed that the memory cell turned ON and the voltage applied to the word line is greater than the threshold voltage of the memory cell.

If the conduction current is measured to be not greater than the certain value, then the memory cell did not turn ON, and the voltage applied to the word line is not greater than the threshold voltage of the memory cell. During a read or verify process, the unselected memory cells are provided with one or more read pass voltages (also referred to as bypass voltages) at their control gates so that these memory cells will operate as pass gates (e.g., conducting current regardless of whether they are programmed or erased).

There are many ways to measure the conduction current of a memory cell during a read or verify operation. In one example, the conduction current of a memory cell is measured by the rate at which the memory cell discharges or charges a dedicated capacitor in a sense amplifier. In another example, the conduction current of the selected memory cell allows (or fails to allow) the NAND string that includes the memory cell to discharge a corresponding bit line. The voltage on the bit line is measured after a period of time to see whether or not the bit line has been discharged. Note that the technology described herein can be used with different methods known in the art for verifying/reading. Other read and verify techniques known in the art also can be used.

As described above, at step 804 a program pulse is applied to the selected word line, and at step 806 memory cells coupled to the selected word line are verified using an appropriate set of verify reference voltages to perform one or more verify operations. Steps 804 and 806 are part of an iterative loop in which program pulses are applied as a series of program pulses that step up in magnitude, with intervening verify reference pulses between consecutive program pulses. Such an iterative loop is referred to herein as a “program-verify iteration.”

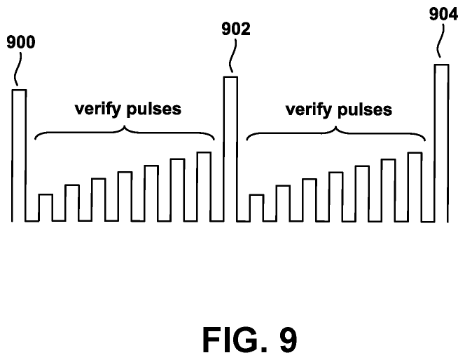

FIG. 9 illustrates an example of such program-verify pulses applied to a selected word line. In particular, FIG. 9 depicts program pulses 900, 902 and 904 applied to the selected word line during three successive iterations of step 804 of FIG. 8. Between program pulses 900, 902 and 904 verify pulses are applied to the selected word line during three successive program-verify iterations of steps 804-806 of FIG. 8 to determine whether threshold voltages of the memory cells are greater than the respective verify reference voltages.

As described above, in embodiments a population of memory cells to be programmed is first erased so that all memory cells in the population are in an erased data state (e.g., state S0 in FIG. 5 or state E in FIG. 7A) prior to programming. When the programmed memory cells are subsequently selected to be re-programmed, the memory cells are again erased prior to programming.

Each program and erase iteration of a memory cell or group of memory cells is referred to herein as a “program-erase cycle.” and the number of program-erase cycles performed on a memory cell or group of memory cells is referred to herein as a “program-erase cycle count” or “PEC.” In embodiments, a Controller Device maintains a record of the program-erase cycle count for each memory cell or group of memory cells of a memory structure (e.g., memory structure 202 of FIG. 2A).

An erase operation for memory cells in a block typically involves one or more “erase-verify iterations,” also referred to as “erase-verify loops,” where each iteration involves channel boosting followed by an erase verify test, until the erase operation is completed.

In an embodiment of an erase-verify loop, the voltages of the channels are boosted while holding the voltages of the word lines at a low level (e.g., VSS). In an embodiment, the channels are boosted by applying one or more erase pulses to the block. In one technique, the erase pulses are applied to the substrate, causing holes to be injected into the channels via the source ends of the NAND strings.

In another technique, erase pulses are applied to select transistors to generate a GIDL current to boost the NAND string channel. Such an erase technique is referred to herein as a “GIDL Erase” operation. In an embodiment, one or more drain erase pulses are applied to a drain terminal of a select transistor of a NAND string while applying a corresponding one or more gate erase pulses each having a magnitude Vsgd to a gate terminal of the select transistor to provide a drain-to-gate voltage of a sufficiently high magnitude (referred to herein as a GIDL voltage or GV) that the select transistor generates a GIDL current. In an embodiment, GIDL current may result in one type of carriers (e.g., holes) predominantly moving into the NAND channel and thereby raising the potential of (e.g., boosting) the channel.

Boosting the channels creates a large channel-to-gate voltage which drives holes into the charge trapping layers, lowering the threshold voltage of each memory cell. An erase verify test, which is a sensing operation, can be performed after applying each erase pulse to determine if the threshold voltage of each memory cell has been lowered below an erase verify voltage. If the threshold voltage of a memory cell is below the erase verify voltage, the memory cell passes the erase verify test. If the threshold voltage of a memory cell is not below the erase verify voltage, the memory cell fails the erase verify test.

In an embodiment, referred to herein as an “all-erase” operation, all memory cells in a block are erased simultaneously. For example, the word lines of all memory cells in a block are biased at a low level (e.g., VSS) and one or more erase pulses having an erase voltage (V_{E}) are applied to the substrate.

In another embodiment, referred to herein as a “stripe erase” operation, in a first erase phase memory cells associated with every other word line of the block are erased simultaneously and then in a second erase phase memory cells associated with the remaining word lines of the block are erased simultaneously (e.g., all even word lines first and then all odd word lines next).

For example, in the first erase phase all even word lines are biased at a low level (e.g., VSS), all odd word lines are biased at erase voltage V_{E}, and one or more erase pulses having erase voltage V_{E} are applied to the substrate. In the second phase, all odd word lines are biased at a low level (e.g., VSS), all even word lines are biased at erase voltage V_{E}, and one or more erase pulses having erase voltage V_{E} are applied to the substrate.

In embodiments, an erase operation for a block completes when fewer than a threshold number of memory cells in the block fail the erase verify test. As used herein, the threshold number is also called a “fail bits threshold number.” The fail bits threshold number is sometimes referred to as a “bitscan pass/fail” or “BSPF” value. In an embodiment, the fail bits threshold number BSPF is the number of bits that can be corrected by error correction codes (ECC) during a read process for the page of memory cells. In other embodiments, other criteria may be used for specifying the fail bits threshold number BSPF. In an embodiment, the fail bits threshold number BSPF has a fixed value. For example, the fail bits threshold number BSPF=25, or some other value.

In embodiment, an erase operation for a block must complete within a maximum number of erase-verify loops (EV_{M}). For example, the maximum number of erase-verify loops EV_{M} may be 6, or some other value. A block erase failure occurs if more than the fail bits threshold number BSPF of memory cells in the block fail erase verify tests within the maximum number of erase-verify loops EV_{M}. For example, if the fail bits threshold number BSPF=25 and the maximum number of erase-verify loops EV_{M}=6, a block erase failure may occur if more than 25 memory cells in the block fail erase verify tests within 6 erase-verify loops.

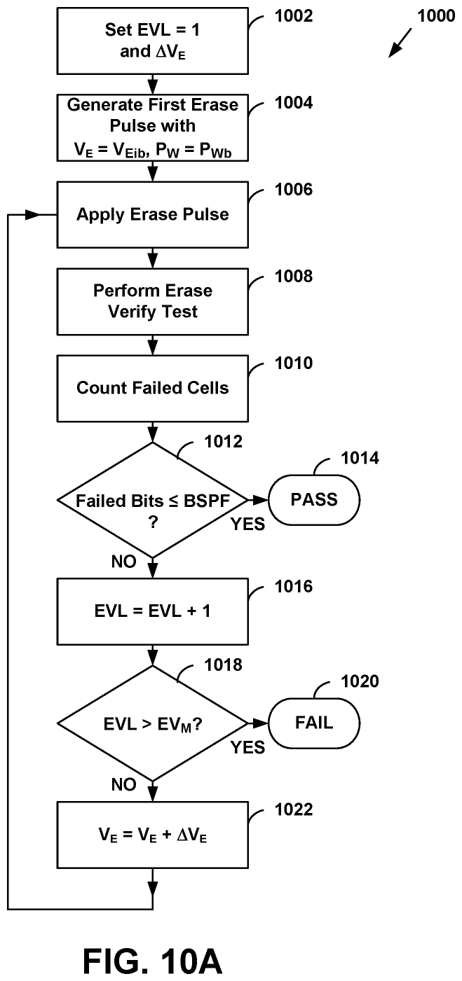

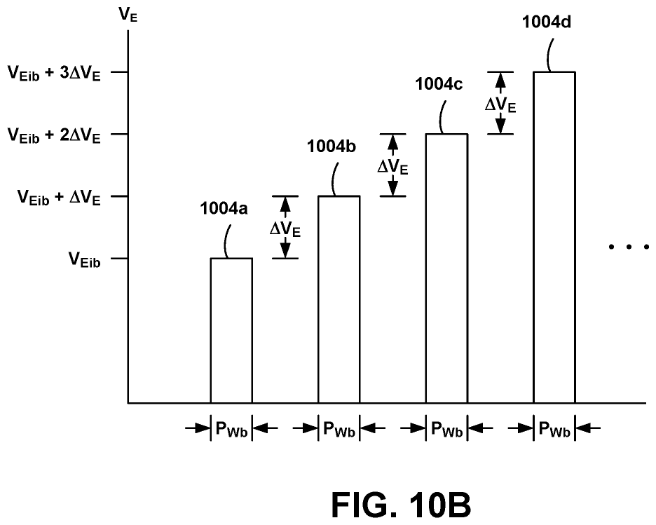

FIG. 10A is a flowchart describing an embodiment of a process 1000 for erasing a population of memory cells (e.g., an erase block of memory cells). In an example embodiment, process 1000 is performed on memory die 106 (FIG. 1) using the control circuits discussed above. For example, process 1000 can be performed at the direction of state machine 216 (FIG. 2).

In an embodiment, state machine 216 maintains an erase-verify loop counter EVL for the block of memory cells in process 1000. In step 1002 of process 1000, erase-verify loop counter EVL is initialized at 1, and an erase voltage step ΔV_{E} is set (e.g., 0.2V or some other value).

In an embodiment, state machine 216 also maintains one or more parameters of a “baseline erase pulse.” In an embodiment, a first baseline erase pulse parameter (BEPP) is a baseline initial erase voltage V_{Eib}. In another embodiment, a second baseline erase pulse parameter is a baseline erase pulse width P_{Wb}. Other baseline erase pulse parameters may be used.

In embodiments, baseline initial erase voltage V_{Eib} and baseline erase pulse width P_{Wb} have values that are selected to achieve a baseline threshold voltage shift without over-erasing or under-erasing the memory cells. For example, baseline initial erase voltage V_{Eib} and baseline erase pulse width P_{Wb} may be determined based on simulations, empirical measurements, or a combination of the two. In an embodiment, baseline initial erase voltage V_{Eib} is between about 12V to about 16V, although other values may be used. In an embodiment, baseline erase pulse width P_{Wb} is between about 0.5 ms and about 1 ms, although other values may be used.

In step 1004 of process 1000, a first erase pulse is generated having parameters equal to the baseline erase pulse parameters. In an embodiment, the first erase pulse has an erase voltage V_{E} equal to baseline initial erase voltage V_{Eib}, and has an erase pulse width P_{W} equal to baseline erase pulse width P_{Wb}.

At step 1006, the first erase pulse having erase voltage V_{E} and erase pulse width P_{W} is applied to the memory cells of the erase block. FIG. 10B depicts example erase pulses 1004a-1004d. Although four erase pulses 1004a-1004d are depicted, more or fewer than four erase pulses may be used. In embodiments, erase pulses 1004a-1004d include parameters such as erase voltage V_{E} and erase pulse width P_{W} that are based on the baseline erase pulse parameters (e.g., baseline initial erase voltage V_{Eib} and baseline erase pulse width P_{Wb}).

In an embodiment, a first erase pulse 1004a has parameters equal to the baseline erase pulse parameters. Thus, as depicted in FIG. 10B, first erase pulse 1004a has an erase voltage V_{E} equal to baseline initial erase voltage V_{Eib} and has an erase pulse width P_{W} equal to baseline erase pulse width P_{Wb}. In an embodiment, all erase pulses 1004a-1004d have the same erase pulse width P_{W} equal to baseline erase pulse width P_{Wb}.

Referring again to FIG. 10A, at step 1008, an erase verify test is performed on the memory cells of the erase block, such as described above.

At step 1010, the memory system counts the number of memory cells in the erase block that have failed the erase verify test. That is, the system counts the number of memory cells in the erase block that have threshold voltages that are not below the erase verify voltage. This counting can be done by state machine 216 (FIG. 2), controller 104 (FIG. 1), or other logic.

At step 1012, a determination is made whether the count from step 1010 is less than or equal to fail bits threshold number BSPF. If a determination is made at step 1012 that the count at step 1010 is less than or equal to fail bits threshold number BSPF, then at step 1014 erase process 1000 is deemed to have passed.

In contrast, if at step 1012 a determination is made that the count at step 1010 is not less than or equal to fail bits threshold number BSPF, then at step 1016 erase-verify loop counter EVL is incremented by 1.

At step 1018, a determination is made whether erase-verify loop counter EVL is greater than the maximum number of erase-verify loops EV_{M}. If erase-verify loop counter EVL is greater than the maximum number of erase-verify loops EV_{M}, then at step 1020 erase process 1000 is deemed to have failed. In other words, within the maximum number of erase-verify loops EV_{M} more than the fail bits threshold number BSPF of memory cells in the erase block fail erase verify tests, and the erase is deemed to have failed.

In contrast, if at step 1018 a determination is made that erase-verify loop counter EVL is less than or equal to the maximum number of erase-verify loops EV_{M}, at step 1022 erase voltage V_{E} is incremented by erase voltage step ΔV_{E}. Process 1000 then loops back to step 1006 and another erase pulse is applied to the memory cells of the erase block.

Referring again to FIG. 10B, all erase pulses 1004b-1004d after first erase pulse 1004a have parameters that are based on the baseline erase pulse parameters (e.g., baseline initial erase voltage V_{Eib} and baseline erase pulse width P_{Wb}). In particular, a second erase pulse 1004b has an erase voltage V_{E} equal to baseline initial erase voltage plus the erase voltage step (V_{Ein}+ΔV_{E}) and has an erase pulse width P_{W} equal to baseline erase pulse width P_{Wb}. Likewise, a third erase pulse 1004c has an erase voltage V_{E} equal to baseline initial erase voltage plus two erase voltage steps (V_{Ein}+2ΔV_{E}) and has an erase pulse width P_{W} equal to baseline erase pulse width P_{Wb}. Similarly, a fourth erase pulse 1004d has an erase voltage V_{E} equal to baseline initial erase voltage plus three erase voltage steps (V_{Ein}+3ΔV_{E}) and has an erase pulse width P_{W} equal to baseline erase pulse width P_{Wb}, and so on.

Thus, referring again to FIG. 10A each pass through steps 1006-1012 is an example of an erase-verify loop. The loop of steps 1006-1022 is repeated until the number of memory cells in the erase block that have failed the erase verify test is less than or equal to fail bits threshold number BSPF (whereby the erase operation passes), or the erase-verify loop counter EVL is greater than the maximum number of erase-verify loops EV_{M} (whereby the erase operation fails).

In process 1000, if at step 1012 a determination is made that the count at step 1010 is less than or equal to fail bits threshold number BSPF then the value of erase-verify loop counter EVL is the number of erase-verify loops required for the erase block to pass the erase verify test of step 1008.

An indication of the time required complete a memory cell erase operation is referred to herein as erase speed, and is described in terms of a number of erase-verify loops required for the memory cell to pass an erase verify test. For example, a first memory cell may pass an erase verify test in 2 erase-verify loops, and a second memory cell may pass the erase verify test in 6 erase-verify loops. In this context, the second memory cell may be said to have a slower erase speed than the first memory cell because the second memory cell requires more erase-verify loops to pass the erase verify test.

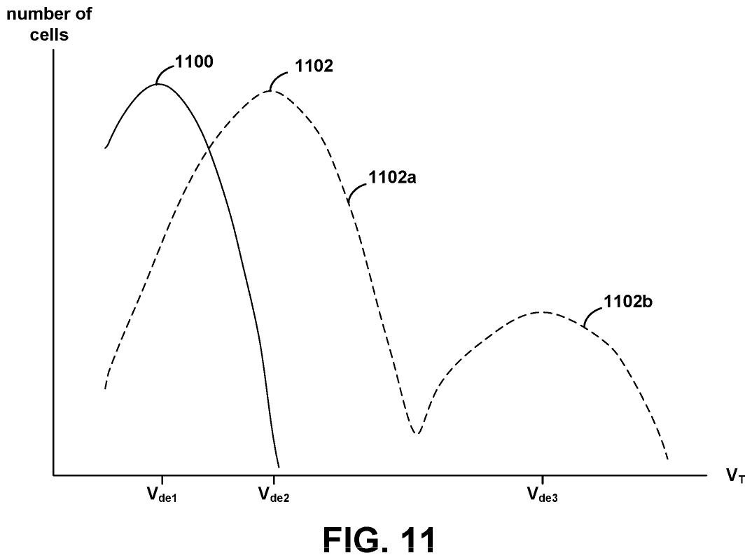

Erase speed tends to slow with increasing program-erase cycle count. In other words, as a memory cell is subjected to increasing program-erase cycle counts the memory cell requires more erase-verify loops to pass the erase verify test. For example, FIG. 11 depicts example erased threshold voltage distributions for a population of memory cells that have been erased using N erase-verify loops. For example, if N=2, each memory cell received N=2 erase pulses.

Curve 1100 depicts an example erased threshold voltage distribution for the population of memory cells at “fresh” (i.e., before any program-erase cycle counts). Curve 1100 has a single bell-shaped curve portion that is centered on a first erase threshold voltage Vde1 and that encompasses substantially all of the memory cells.

In contrast, curve 1102 depicts an example erased threshold voltage distribution for the same population of memory cells after M program-erase cycle counts (e.g., M=100k program-erase cycle counts). Curve 1102 includes a first bell-shaped curve portion 1102a that is centered on a second erase threshold voltage Vde2, and a second bell-shaped curve portion 1102b that is centered on a third erase threshold voltage Vde3. First bell-shaped curve portion 1102a and second bell-shaped curve portion 1102b collectively encompass substantially all of the memory cells.

As depicted in FIG. 11, after M=100k program-erase cycle counts substantially all of the memory cells are slower to erase than at fresh. In particular, after the same number of erase-verify loops (e.g., N=2), the threshold voltages of the memory cells after M=100k program-erase cycle counts are higher than the threshold voltages of the memory cells at fresh. The higher threshold voltages at high program-erase cycle counts results in an increase in a number of memory cells failing the erase verify test, which in turn results in an increase in the number of erase verify loops needed to pass erase verify.

As a result of process variations, in a population of memory cells the decrease in erase speed with increasing program-erase cycle count may vary considerably. Thus, for some memory cells (the “less slow memory cells”), the decrease in erase speed with increasing program-erase cycle count may be relatively minor. Nevertheless, at high program-erase cycle counts such less slow memory cells are still subjected to an increase in the number of erase verify loops needed for a sufficient number of memory cells to pass erase verify. This results in an unnecessary deeper erase of the less slow memory cells, and eventual erase failure.

Without wanting to be bound by any particular theory, it is believed that the increase in failed bit count and erase failure with increasing program-erase cycle count results from cycling damage caused by high electric fields across the memory cells during erase operations. Without wanting to be bound by any particular theory, it is believed that reducing electric fields across the memory cells during erase operations may reduce such cycling damage.

Indeed, without wanting to be bound by any particular theory, it is believed that programmed memory cells undergo higher effective erase electric fields during erase operations compared with un-programmed memory cells. In addition, without wanting to be bound by any particular theory, it is believed that programmed memory cells suffer the highest erase stress during cycling. Further, without wanting to be bound by any particular theory, it is believed that due to erase dispersion the difference between the electric fields across programmed memory cells and un-programmed memory cells is much higher for the first erase pulse.

Thus, technology is described for erasing memory cells by applying a “weaker” first erase pulse, then resuming “normal” erase pulses for the second and any subsequent erase pulses applied to the memory cells. In an embodiment, memory cells are erased using a first erase pulse that has a parameter selected so that the first erase pulse does not erase the memory cells.

In embodiments, memory cells are erased using a first erase pulse that includes a desired amount of variation from a baseline erase pulse parameter. In embodiments, the desired amount of variation is selected to reduce erase-induced damage to the memory cells. In an embodiment, the desired amount of variation is selected so that the first erase pulse does not erase the memory cells.

In embodiments, memory cells are erased using a second and any subsequent pulses that include a parameter based on the baseline erase pulse parameter but without the desired amount of variation from the baseline erase pulse parameter.

In an embodiment, an erase voltage of the first erase pulse is lower than a baseline initial erase voltage V_{Ei}. In another embodiment, an erase pulse width of the first erase pulse is shorter than a baseline erase pulse width P_{Wb}. In another embodiment, an erase voltage of the first erase pulse is lower than a baseline initial erase voltage V_{Ei}, and an erase pulse width of the first erase pulse is shorter than a baseline erase pulse width P_{Wb}. In embodiments, any second and subsequent erase pulses have erase voltages and erase pulse widths that are based on the baseline initial erase voltage V_{Ei} and the baseline erase pulse width P_{Wb}, respectively.

Without wanting to be bound by any particular theory, it is believed that erasing memory cells using a first erase pulse that includes a desired amount of variation from a baseline erase pulse parameter may reduce erase-induced damage to the memory cells.

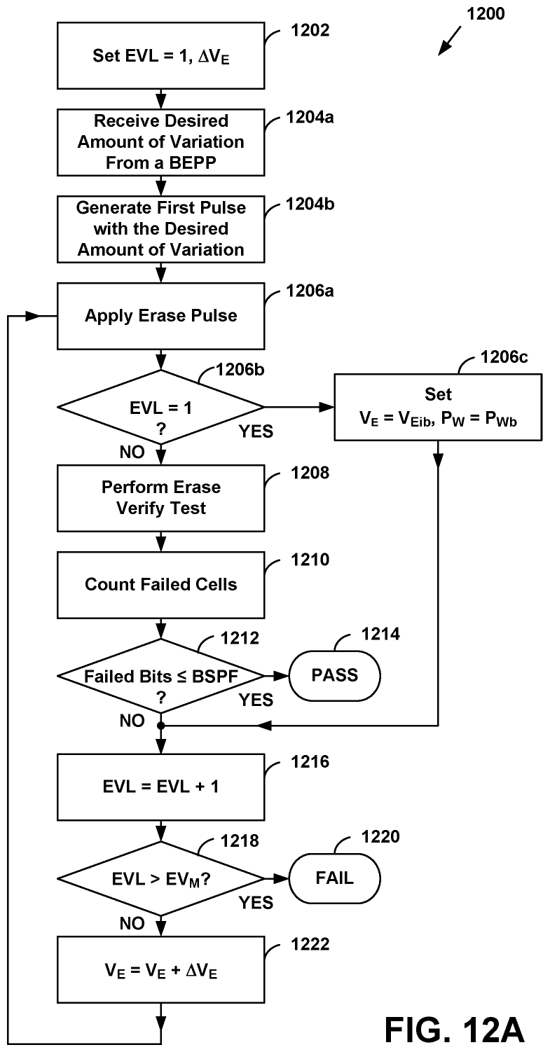

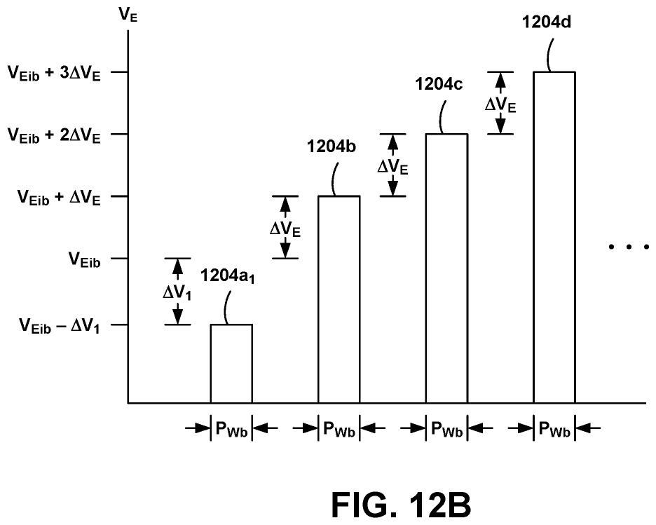

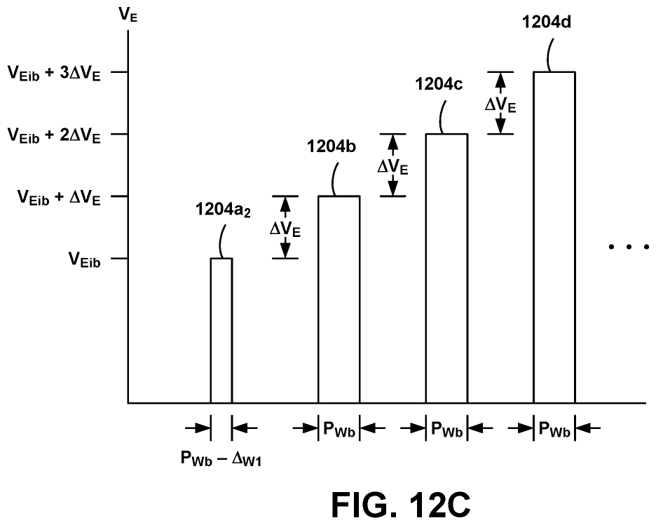

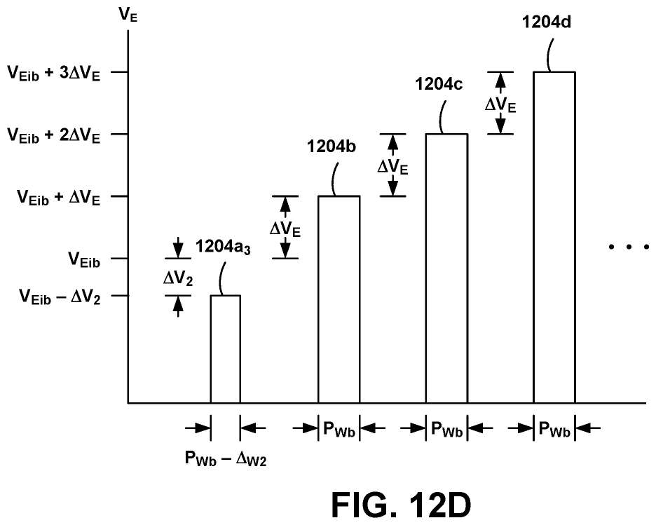

FIG. 12A is a flowchart describing an embodiment of a process 1200 for erasing a population of memory cells (e.g., an erase block of memory cells). In an example embodiment, process 1200 is performed on memory die 106 (FIG. 1) using the control circuits discussed above. For example, process 1200 can be performed at the direction of state machine 216 (FIG. 2).

In an embodiment, state machine 216 maintains an erase-verify loop counter EVL for the block of memory cells in process 1200. In step 1202 of process 1200, erase-verify loop counter EVL is initialized at 1, and an erase voltage step ΔV_{E} is set (e.g., 0.2V or some other value).

In an embodiment, state machine 216 also maintains baseline erase pulse parameters, such as baseline initial erase voltage V_{Eib} and baseline erase pulse width P_{Wb}, described above in connection with process 1000 of FIG. 10A. Other baseline erase pulse parameters may be used.

In step 1204a of process 1200, a desired amount of variation from one or more baseline erase pulse parameters is received. For example, state machine 216 may receive a first amount of a desired reduction from baseline initial erase voltage V_{Eib} and/or a second amount of a desired reduction from baseline erase pulse width P_{Wb}. Without wanting to be bound by any particular theory, it is believed that the first amount of a desired reduction from baseline initial erase voltage V_{Eib} and/or the second amount of a desired reduction from baseline erase pulse width P_{Wb} may reduce erase-induced damage to the memory cells being erased.

In step 1204b of process 1200, a first erase pulse is generated that includes the desired amount of variation from the baseline erase pulse parameter specified in step 1204a. For example, if a first amount of desired reduction from baseline initial erase voltage V_{Eib} is received at step 1204a, at step 1204b the first erase pulse will be generated having an erase voltage V_{E} equal to baseline initial erase voltage V_{Eib} minus the first amount of desired reduction, and having an erase pulse width P_{W} equal to baseline erase pulse width P_{Wb}.

FIG. 12B depicts an example of erase voltage pulses, including a first erase pulse 1204a1 that has an erase voltage V_{E} equal to baseline initial erase voltage V_{Eib} minus a first amount of desired reduction (ΔV₁), and has an erase pulse width P_{W} equal to baseline erase pulse width P_{Wb}. In an embodiment, first amount of desired reduction ΔV₁ is selected so that first erase pulse 1204a1 does not erase the memory cells.

In another example, if a second amount of desired reduction from baseline erase pulse width P_{Wb} is received at step 1204a, at step 1204b the first erase pulse will be generated having an erase voltage V_{E} equal to baseline initial erase voltage V_{Eib} and having an erase pulse width P_{W} equal to baseline erase pulse width P_{Wb} minus the second amount of desired reduction.

FIG. 12C depicts another example of erase voltage pulses, including a first erase pulse 1204a2 that has an erase voltage V_{E} equal to baseline initial erase voltage V_{Eib}, and has an erase pulse width P_{W} equal to baseline erase pulse width P_{Wb} minus a second amount of desired reduction (Δ_{W1}). In an embodiment, second amount of desired reduction Δ_{W1} is selected so that first erase pulse 1204a2 does not erase the memory cells.

In another example, if a third amount of desired reduction from baseline initial erase voltage V_{Eib} and a fourth amount of desired reduction from baseline erase pulse width P_{Wb} are received at step 1204a, at step 1204b the first erase pulse will be generated having an erase voltage V_{E} equal to baseline initial erase voltage V_{Eib} minus the third amount of desired reduction and having an erase pulse width P_{W} equal to baseline erase pulse width P_{Wb} minus the fourth amount of desired reduction.

FIG. 12D depicts still another example of erase voltage pulses, including a first erase pulse 1204a3 that has an erase voltage V_{E} equal to baseline initial erase voltage V_{Eib} minus a third amount of desired reduction (ΔV₂), and has an erase pulse width P_{W} equal to baseline erase pulse width P_{Wb} minus a fourth amount of desired reduction (Δ_{W2}). In an embodiment, third amount of desired reduction ΔV₂ and fourth amount of desired reduction ΔW₂ are selected so that first erase pulse 1204a3 does not erase the memory cells.

At step 1206a, the first erase pulse having erase voltage V_{E} and erase pulse width P_{W} set in step 1204b is applied to the memory cells of the erase block.

At step 1206b, a determination is made whether the erase pulse applied in step 1206a is the first erase pulse (e.g., EVL=1). If a determination is made at step 1206b that the erase pulse applied in step 1206a is not the first erase pulse (e.g., EVL>1), at step 1208, an erase verify test is performed on the memory cells of the erase block, such as described above.

At step 1210, the memory system counts the number of memory cells in the erase block that have failed the erase verify test. That is, the system counts the number of memory cells in the erase block that have threshold voltages that are not below the erase verify voltage. This counting can be done by state machine 216 (FIG. 2), controller 104 (FIG. 1), or other logic.

At step 1212, a determination is made whether the count from step 1210 is less than or equal to fail bits threshold number BSPF. If a determination is made at step 1212 that the count at step 1210 is less than or equal to fail bits threshold number BSPF, then at step 1214 erase process 1200 is deemed to have passed.

In contrast, if at step 1212 a determination is made that the count at step 1210 is not less than or equal to fail bits threshold number BSPF, then at step 1216 erase-verify loop counter EVL is incremented by 1.

At step 1218, a determination is made whether erase-verify loop counter EVL is greater than the maximum number of erase-verify loops EV_{M}. If erase-verify loop counter EVL is greater than the maximum number of erase-verify loops EV_{M}, then at step 1220 erase process 1200 is deemed to have failed. In other words, within the maximum number of erase-verify loops EV_{M} more than the fail bits threshold number BSPF of memory cells in the erase block fail erase verify tests, and the erase is deemed to have failed.

In contrast, if a determination is made at step 1218 that erase-verify loop counter EVL is less than or equal to the maximum number of erase-verify loops EV_{M}, at step 1222 erase voltage V_{E} is incremented by erase voltage step ΔV_{E}. Process 1200 then loops back to step 1206a and another erase pulse is applied to the memory cells of the erase block.

If, however, a determination is made at step 1206b that EVL=1, then at step 1206c erase voltage V_{E} is made equal to baseline initial erase voltage V_{Eib}, and erase pulse width P_{W} is made equal to baseline erase pulse width P_{Wb}. Process 1200 then proceeds to steps 1216-1222 as described above, and loops back to step 1206a.

Because at step 1206c erase voltage V_{E} is made equal to baseline initial erase voltage V_{Eib}, and erase pulse width P_{W} is made equal to baseline erase pulse width P_{Wb}, and because at step 1222 erase voltage V_{E} is incremented by erase voltage step ΔV_{E}, when process 1200 loops back to step 1206a a second erase pulse is generated that has an erase voltage V_{E} equal to baseline initial erase voltage V_{Eib} plus erase voltage step ΔV_{E}, and has an erase pulse width P_{W} is made equal to baseline erase pulse width P_{Wb}.

In this regard, the second erase pulse (and any subsequent erase pulses) has a first parameter (erase voltage V_{E}) and a second parameter (erase pulse width P_{w}) that are based on the corresponding baseline erase pulse parameters and without the desired amount of variation from the baseline erase pulse parameter specified in step 1204a. In this regard, only the first erase pulse includes the desired amount of variation from the baseline erase pulse parameter specified in step 1204a.

Thus, referring again to FIGS. 12B-12D, all erase pulses 1204b-1204d after first erase pulses 1204a1 (FIG. 12B), 1204a2 (FIG. 12C), and 1204a3 (FIG. 12D) have parameters that are based only on the baseline erase pulse parameters (e.g., baseline initial erase voltage V_{Eib} and baseline erase pulse width P_{Wb}) and without the desired amount of variation from the baseline erase pulse parameter specified in step 1204a. Also, erase pulses 1204b-1204d of FIGS. 12B-12D are the same as erase pulses 1004b-1004d, respectively, of FIG. 10B.

In particular, in each of FIGS. 12B-12D a second erase pulse 1204b has an erase voltage V_{E} equal to baseline initial erase voltage plus the erase voltage step (V_{Ein}+ΔV_{E}) and has an erase pulse width P_{W} equal to baseline erase pulse width P_{Wb}. Indeed, second erase pulse 1204b of FIGS. 12B-12D is the same as second erase pulse 1004b of FIG. 10B.

Likewise, in each of FIGS. 12B-12D a third erase pulse 1204c has an erase voltage V_{E} equal to baseline initial erase voltage plus two erase voltage steps (V_{Ein}+2ΔV_{E}) and has an erase pulse width P_{W} equal to baseline erase pulse width P_{Wb}. Indeed, third erase pulse 1204c of FIGS. 12B-12D is the same as third erase pulse 1004c of FIG. 10B.

Similarly, in each of FIGS. 12B-12D a fourth erase pulse 1204d has an erase voltage V_{E} equal to baseline initial erase voltage plus three erase voltage steps (V_{Ein}+3ΔV_{E}) and has an erase pulse width P_{W} equal to baseline erase pulse width P_{Wb}, and so on. Indeed, fourth erase pulse 1204d of FIGS. 12B-12D is the same as fourth erase pulse 1004d of FIG. 10B.

In embodiments, process 1200 of FIG. 12A may be used in an all-erase operation, in which all memory cells in a block are erased simultaneously. In other embodiments, process 1200 of FIG. 12A may be used in a stripe erase operation, in which in a first erase phase memory cells associated with every other word line of the block are erased simultaneously and then in a second erase phase memory cells associated with the remaining word lines of the block are erased simultaneously (e.g., all even word lines first and then all odd word lines next).

In an embodiment of process 1200 used in a stripe erase operation, the first erase pulse of process 1200 may be applied with all word lines biased at a low level (e.g., VSS). After the first erase pulse is applied, stripe erase operation (e.g., even/odd) may resume for the second and any subsequent erase pulses. Without wanting to be bound by any particular theory, it is believed that such an implementation of a stripe erase operation may reduce an erase time penalty typically incurred by conventional stripe erase operations.

As described above, in a GIDL Erase operation erase pulses are applied to select transistors to generate a GIDL current to boost the NAND string channel. In an embodiment, a GIDL Erase operation includes applying a drain erase pulse to a drain terminal of a select transistor while applying a gate erase pulse to a gate terminal of the select transistor. In an embodiment, the drain erase pulse and the corresponding gate erase pulse provide a GIDL voltage (GV) to the select transistor.

In an embodiment, one or more drain erase pulses each having an erase voltage V_{E} are applied to a drain terminal of a select transistor while applying a corresponding one or more gate erase pulses each having a magnitude Vsgd to a gate terminal of the select transistor. In an embodiment, each drain erase pulse and corresponding gate erase pulse provide a GIDL voltage GV to the select transistor: GV=(V_{E}-Vsgd).

In embodiments, process 1200 of FIG. 12A may be used in a GIDL erase operation. In an embodiment, for a first erase pulse includes a drain erase pulses having an erase voltage V_{E} that includes a first amount of a desired reduction from baseline initial erase voltage V_{Eib} and/or a second amount of a desired reduction from baseline erase pulse width P_{Wb}.

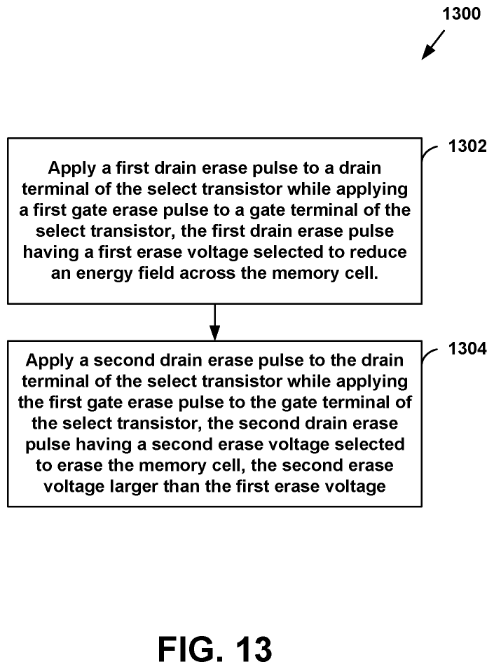

FIG. 13 depicts a flowchart describing an embodiment of a process 1300 using gate induced drain leakage to erase a memory cell that is coupled to a select transistor. At step 1302, apply a first drain erase pulse to a drain terminal of the select transistor while applying a first gate erase pulse to a gate terminal of the select transistor, the first drain erase pulse having a first erase voltage selected to reduce an energy field across the memory cell. At step 1304, apply a second drain erase pulse to the drain terminal of the select transistor while applying the first gate erase pulse to the gate terminal of the select transistor, the second drain erase pulse having a second erase voltage selected to erase the memory cell, the second erase voltage larger than the first erase voltage.

One embodiment includes an apparatus that includes a block of memory cells, and a control circuit coupled to the block of memory cells. The control circuit is configured to perform an erase operation on the block of memory cells by receiving a desired amount of variation from a baseline erase pulse parameter, generating a first erase pulse that includes the desired amount of variation from the baseline erase pulse parameter, and applying the first erase pulse to the block of memory cells. The desired amount of variation from the baseline erase pulse is selected to reduce erase-induced damage to the block of memory cells.

One embodiment includes an apparatus that includes a block of memory cells, and a control circuit coupled to the block of memory cells. The control circuit is configured to perform an erase operation on the block of memory cells in a plurality of erase-verify loops. In a first erase-verify loop the control circuit is configured to apply a first erase pulse to the block of memory cells. The first erase pulse has a parameter selected so that the first erase pulse does not erase the block of memory cells.

One embodiment includes a method that includes performing an erase operation on a memory cell that is coupled to a select transistor by applying a first drain erase pulse to a drain terminal of the select transistor while applying a first gate erase pulse to a gate terminal of the select transistor, and applying a second drain erase pulse to the drain terminal of the select transistor while applying the first gate erase pulse to the gate terminal of the select transistor. The first drain erase pulse has a first erase voltage selected to reduce an energy field across the memory cell. The second drain erase pulse has a second erase voltage selected to erase the memory cell. The second erase voltage is larger than the first erase voltage.

For purposes of this document, reference in the specification to “an embodiment,” “one embodiment,” “some embodiments,” or “another embodiment” may be used to describe different embodiments or the same embodiment.

For purposes of this document, a connection may be a direct connection or an indirect connection (e.g., via one or more other parts). In some cases, when an element is referred to as being connected or coupled to another element, the element may be directly connected to the other element or indirectly connected to the other element via intervening elements. When an element is referred to as being directly connected to another element, then there are no intervening elements between the element and the other element. Two devices are “in communication” if they are directly or indirectly connected so that they can communicate electronic signals between them.

For purposes of this document, the term “based on” may be read as “based at least in part on.”

For purposes of this document, without additional context, use of numerical terms such as a “first” object, a “second” object, and a “third” object may not imply an ordering of objects, but may instead be used for identification purposes to identify different objects.

For purposes of this document, the term “set” of objects may refer to a “set” of one or more of the objects.

The foregoing detailed description has been presented for purposes of illustration and description. It is not intended to be exhaustive or to limit to the precise form disclosed. Many modifications and variations are possible in light of the above teaching. The described embodiments were chosen in order to best explain the principles of the proposed technology and its practical application, to thereby enable others skilled in the art to best utilize it in various embodiments and with various modifications as are suited to the particular use contemplated. It is intended that the scope be defined by the claims appended hereto.

1. An apparatus comprising:
a block of memory cells; and
a control circuit coupled to the block of memory cells, the control circuit configured to perform an erase operation on the block of memory cells by:
receiving a desired amount of variation from a baseline erase pulse parameter;
generating a first erase pulse comprising the desired amount of variation from the baseline erase pulse parameter; and
applying the first erase pulse to the block of memory cells,
wherein the desired amount of variation from the baseline erase pulse parameter is selected to reduce erase-induced damage to the block of memory cells.

2. The apparatus of claim 1, wherein the desired amount of variation from the baseline erase pulse parameter is selected to reduce an energy field across memory cells in the block of memory cells during the erase operation.

3. The apparatus of claim 1, wherein the baseline erase pulse parameter comprises a baseline initial erase voltage.

4. The apparatus of claim 3, wherein the first erase pulse comprises an erase voltage lower than the baseline initial erase voltage.

5. The apparatus of claim 1, wherein the baseline erase pulse parameter comprises a baseline erase pulse width.

6. The apparatus of claim 5, wherein the first erase pulse comprises an erase pulse width shorter than the baseline erase pulse width.

7. The apparatus of claim 1, wherein the first erase pulse comprises an erase voltage lower than a baseline initial erase voltage and an erase pulse width shorter than a baseline erase pulse width.

8. The apparatus of claim 1, wherein the control circuit is further configured to perform an erase verify test on the block of memory cells.

9. The apparatus of claim 1, wherein the control circuit is further configured to apply a second erase pulse to the block of memory cells without first performing an erase verify test on the block of memory cells.

10. The apparatus of claim 1, wherein the control circuit is further configured to:
generate a second erase pulse having a parameter based on the baseline erase pulse parameter but without the desired amount of variation from the baseline erase pulse parameter; and
apply the second erase pulse to the block of memory cells.

11. The apparatus of claim 10, wherein:
the baseline erase pulse parameter comprises a baseline initial erase voltage; and
the second erase pulse comprises an erase voltage equal to the baseline initial erase voltage plus an erase voltage step.

12. The apparatus of claim 10, wherein:
the baseline erase pulse parameter comprises a baseline erase pulse width; and
the second erase pulse comprises an erase pulse width equal to the baseline erase pulse width.

13. The apparatus of claim 1, wherein the control circuit is further configured to apply erase pulses to the block of memory cells in a plurality of erase-verify iterations.

14. The apparatus of claim 1, wherein the control circuit is further configured to:
in a first erase phase apply erase pulses to memory cells associated with every other word line of the block; and
in a second erase phase apply erase pulses to memory cells associated with remaining word lines of the block.

15. An apparatus comprising:
a block of memory cells; and
a control circuit coupled to the block of memory cells, the control circuit configured to perform an erase operation on the block of memory cells in a plurality of erase-verify loops,
wherein in a first erase-verify loop the control circuit is configured to apply a first erase pulse to the block of memory cells, the first erase pulse comprising a parameter selected so that the first erase pulse does not erase the block of memory cells.

16. The apparatus of claim 15, wherein the first erase pulse comprises an erase voltage that is selected to reduce an energy field across memory cells in the block of memory cells during the erase operation.

17. The apparatus of claim 15, wherein the first erase pulse comprises an erase pulse width that is selected to reduce an energy field across memory cells in the block of memory cells during the erase operation.

18. The apparatus of claim 15, wherein the control circuit is further configured to apply a second erase pulse to the block of memory cells without first performing an erase verify test on the block of memory cells.

19. A method comprising:
performing an erase operation on a memory cell that is coupled to a select transistor by:
applying a first drain erase pulse to a drain terminal of the select transistor while applying a first gate erase pulse to a gate terminal of the select transistor, the first drain erase pulse comprising a first erase voltage selected to reduce an energy field across the memory cell; and
applying a second drain erase pulse to the drain terminal of the select transistor while applying the first gate erase pulse to the gate terminal of the select transistor, the second drain erase pulse comprising a second erase voltage selected to erase the memory cell, the second erase voltage larger than the first erase voltage.

20. The method of claim 19, wherein the first drain erase pulse and the second drain erase pulse generate a gate induced drain leakage current.
